(19) United States
(12) Patent Application Publication
(10) Pub. No.: US 2024/0263070 A1
(43) Pub. Date: Aug. 8, 2024

(54) OXIDE PHOSPHOR, LIGHT-EMITTING DEVICE, AND METHOD FOR PRODUCING OXIDE PHOSPHOR

(71) Applicant: NICHIA CORPORATION, Anan-shi (JP)

(72) Inventor: Yoshinori MURAZAKI, Komatsushima-shi (JP)

(73) Assignee: NICHIA CORPORATION, Anan-shi (JP)

(21) Appl. No.: 18/564,084

(22) PCT Filed: Nov. 25, 2021
(86) PCT No.: PCT/JP2021/043143

§ 371 Date: Nov. 25, 2023

(30) Foreign Application Priority Data
May 26, 2021 (JP) 2021-088394
Sep. 13, 2021 (JP) 2021-148708

(51) Int. Cl. C09K 11/68; C09K 11/77

(52) U.S. Cl. CPC C09K 11/68; C09K 11/7739

(57) ABSTRACT

Provided is an oxide phosphor having a light emission peak wavelength of 800 nm or greater. The oxide phosphor has a composition containing Mg, Ga, O, and Cr, and optionally containing a first element M¹, a second element M², and a third element M³. When a total molar ratio of Ga, Cr, the second element M², and the third element M³ per mole of the composition of the oxide phosphor is 2, the molar ratio of Mg or the molar ratio of a total of Mg and the first element M¹ is in a range from 0.7 to 1.3, the molar ratio of O is in a range of 3.7 to 4.3, and the molar ratio of Cr is in a range greater than 0.02 and 0.3 or less. The oxide phosphor has a light emission peak wavelength in a range of 800 nm to 1600 nm in a light emission spectrum.

### TECHNICAL FIELD

The present disclosure relates to an oxide phosphor, a light-emitting device, and a method for producing the oxide phosphor.

### BACKGROUND ART

A light-emitting device having a light emission intensity in a wavelength ranging from red light to near-infrared light is desirably used in, for example, infrared cameras, infrared communications, light sources for plant growth and cultivation, vein authentication, which is a type of biometric authentication, and food component analysis instruments for non-destructively measuring the sugar content of foods such as fruits and vegetables. Light-emitting devices that emit light in the visible wavelength range as well as in the red to near-infrared wavelength range are also desired.

An example of such a light-emitting device is a light-emitting device in which a light-emitting diode (LED) and a phosphor are combined.

Patent Document 1 discloses a phosphorescent phosphor composed of chromium-activated gallate, and indicates that the phosphorescent phosphor is used as a display or light source in a dark place and emits light having a light emission peak wavelength in a red light range of 660 nm to 720 nm when excited by ultraviolet rays of 254 nm.

### CITATION LIST

### Patent Document

Patent Document 1: JP 10-259375 A

### SUMMARY OF INVENTION

### Technical Problem

Light sources used in small analytical instruments for medical use or food product use may be required in some cases to emit light having a light emission peak wavelength in the near infrared range exceeding 720 nm.

Thus, an object of the present disclosure is to provide an oxide phosphor having a light emission peak wavelength in the near infrared light wavelength range of 800 nm or greater, a light-emitting device using the oxide phosphor, and a method for producing the oxide phosphor.

### Solution to Problem

A first aspect is an oxide phosphor having a composition containing Mg, Ga, O (oxygen), and Cr, the composition optionally containing: at least one first element M¹ selected from the group consisting of Ca, Sr, Ba, Ni, and Zn; at least one second element M² selected from the group consisting of B, Al, In, and Sc; and at least one third element M³ selected from the group consisting of Eu, Ce, Tb, Pr, Nd, Sm, Yb, Ho, Er, Tm, and Mn, in which, when a total molar ratio of Ga, Cr, the second element M², and the third element M³ per mole of the composition of the oxide phosphor is 2, the molar ratio of Mg or a molar ratio of a total of Mg and the first element M¹ when the first element M¹ is included is in a range of 0.7 to 1.3, the molar ratio of O is in a range of 3.7 to 4.3, the molar ratio of Cr is in a range greater than 0.02 and 0.3 or less, and further, when the molar ratio of a total of Mg and the first element M¹ is 1, the molar ratio of the first element M¹ is in a range of 0 to 0.8, the molar ratio of the second element M² is in a range of 0 to 1.6, the molar ratio of the third element M³ is in a range of 0 to 0.2, the molar ratio of the third element M³ being smaller than the molar ratio of Cr, and in which in a light emission spectrum of the phosphor, the oxide phosphor has a light emission peak wavelength in a range of 800 nm to 1600 nm.

A second aspect is a light-emitting device including the above-mentioned oxide phosphor and a light-emitting element that has a light emission peak wavelength in a range of 365 nm to 500 nm, the light-emitting element irradiating the oxide phosphor.

A third aspect is a method for producing an oxide phosphor, the method including: preparing a first compound containing Mg, a second compound containing Ga, a third compound containing Cr, and optionally, a fourth compound containing at least one first element M¹ selected from the group consisting of Ca, Sr, Ba, Ni, and Zn, a fifth compound containing at least one second element M² selected from the group consisting of B, Al, In, and Sc, and a sixth compound containing at least one third element M³ selected from the group consisting of Eu, Ce, Tb, Pr, Nd, Sm, Yb, Ho, Er, Tm, and Mn; preparing a raw material mixture including the first compound, the second compound, the third compound, and optionally, the fourth compound, the fifth compound, or the sixth compound that have been adjusted and mixed such that, when a total molar ratio of Ga, Cr, the second element M², and the third element M³ per mole of the composition of the oxide phosphor is 2, a molar ratio of Mg or a molar ratio of a total of Mg and the first element M¹ when the first element M¹ is included is in a range of 0.7 to 1.3, a molar ratio of Cr is in a range greater than 0.02 and 0.3 or less, and when the molar ratio of a total of Mg and the first element M¹ is 1, the molar ratio of the first element M¹ is in a range of 0 to 0.8, the molar ratio of the second element M² is in a range of 0 to 1.6, the molar ratio of the third element M³ is in a range of 0 to 0.2, and the molar ratio of the third element M³ is smaller than the molar ratio of Cr; and obtaining an oxide phosphor by heat-treating the raw material mixture in an atmosphere containing oxygen at a temperature in a range of 1200° C. to 1700° C., in which at least one selected from the group consisting of the first compound, the second compound, and the third compound is an oxide.

### Advantageous Effects of Invention

According to one aspect of the present disclosure, an oxide phosphor having a light emission peak wavelength in the near infrared light wavelength range of 800 nm to 1600 nm, a light-emitting device in which the oxide phosphor is used, and a method for producing the oxide phosphor can be provided.

### BRIEF DESCRIPTION OF DRAWINGS

FIG. 1 is a schematic cross-sectional view illustrating one example of first configurational example of a light-emitting device.

FIG. 2 is a schematic cross-sectional view illustrating another example of the first configurational example of the light-emitting device.

FIG. 3A is a schematic plan view illustrating a second configurational example of the light-emitting device.

FIG. 3B is a schematic cross-sectional view illustrating the second configurational example of the light-emitting device.

FIG. 4 is an SEM photograph of an oxide phosphor according to Example 3.

FIG. 5 is a graph illustrating emission spectra of oxide phosphors according to Examples 1 to 3.

FIG. 6 is a graph illustrating emission spectra of oxide phosphors according to Example 4 to 6.

FIG. 7 is a graph illustrating emission spectra of oxide phosphors according to Examples 7 to 9.

FIG. 8 is a graph illustrating emission spectra of oxide phosphors according to Examples 10 to 12.

FIG. 9 is a graph illustrating emission spectra of oxide phosphors according to Examples 13 to 15.

FIG. 10 is a graph illustrating an absorption spectrum of the oxide phosphor according to Example 3.

FIG. 11 is a graph illustrating emission spectra of oxide phosphors according to Comparative Examples 1 and 2.

FIG. 12 is a graph illustrating emission spectra of oxide phosphors according to Comparative Examples 3 and 4.

FIG. 13 is a graph illustrating emission spectra of light-emitting devices according to Examples 1 and 2.

FIG. 14 is a graph illustrating emission spectra of oxide phosphors according to Examples 16 to 18.

FIG. 15 is a graph illustrating emission spectra of oxide phosphors according to Examples 19 to 21.

FIG. 16 is a graph illustrating emission spectra of oxide phosphors according to Examples 22 to 24.

### DESCRIPTION OF EMBODIMENTS

Hereinafter, an oxide phosphor, a light-emitting device using the same, and a method for producing the oxide phosphor according to the present disclosure will be described. However, the embodiments presented below are examples for embodying a technical concept of the present invention, and the present invention is not limited to the following oxide phosphor, light-emitting device, and method for producing the oxide phosphor. Note that with regard to visible light, the relationship between the color name and the chromaticity coordinates, the relationship between the wavelength range of light and the color name of monochromatic light, and the like conform to JIS Z 8110.

A light-emitting device is required to emit light in an optimum wavelength range according to the object to be viewed and the usage conditions. For example, medical devices used in medical settings and in daily physical condition management or the like may be required to easily obtain in vivo information. A living body contains light absorbers such as, for example, water, hemoglobin, and melanin. For example, hemoglobin has a high absorption rate of light in a wavelength range of visible light having a wavelength of less than 650 nm, but with a light-emitting device that emits light in the wavelength range of visible light, light in the wavelength range of visible light does not easily penetrate into a living body, and thus in vivo information is not easily obtained. For this reason, there is a range called a “biological window” through which light easily penetrates into the living body. A light-emitting device that emits light in a wavelength range of highly transmissive near-infrared light including at least a portion of the “biological window” range, for example, a range of 800 nm to 1300 nm, may be required. For example, if an increase or decrease in the concentration of oxygen in blood in a living body can be measured by an increase or decrease in the absorption of light by hemoglobin that binds to oxygen, in vivo information can be easily obtained by irradiating with light from the light-emitting device. Therefore, the phosphor used in the light-emitting device may be required to have a light emission peak wavelength in a range of 800 nm to 1300 nm, preferably from 800 nm to 1200 nm, and more preferably from 800 nm to 1000 nm.

For example, in the food products field, a demand exists for a nondestructive saccharimeter for measuring the sugar content of fruits and vegetables in a nondestructive manner, and for a nondestructive taste meter for rice, and the like. Near-infrared spectroscopy is sometimes used as a method for non-destructively measuring internal quality such as the sugar content, acidity, ripeness, and internal damage of fruits and vegetables, and surface layer quality such as abnormal dryness appearing on the peel surface or peel surface layer near the peel surface of fruits and vegetables. In near-infrared spectroscopy, a fruit or vegetable is irradiated with light in the wavelength range of near-infrared light, transmitted light transmitted through the fruit or vegetable or reflected light reflected by the fruit or vegetable is received, and the quality of the fruit or vegetable is measured by a decrease in the intensity of light (absorption of light). A light source such as a tungsten lamp or a xenon lamp is used in a near-infrared spectroscopy-based analyzer used in such food product fields.

In some cases, a light-emitting device that emits light not only in a range of wavelengths from 800 nm to 1600 nm but also in a range of wavelengths from 365 nm to less than 700 nm may be required. For example, in some cases, light emission in a wavelength range of visible light may be required not only to obtain internal information of a living body or a fruit or vegetable but also to enhance visibility of an object.

The phosphorescent phosphor described in Patent Document 1 above is excited by ultraviolet rays of 254 nm, for example, and has a light emission peak wavelength of 706 nm, which is less than 800 nm. Therefore, light emission in a range of wavelengths from 800 nm to 1000 nm for obtaining internal information of a living body or a fruit or vegetable cannot be sufficiently obtained. In addition, the phosphorescent phosphor described in Patent Document 1 is excited by, for example, ultraviolet rays of 254 nm, and therefore light emission in a wavelength range of visible light from 365 nm to 700 nm for visibility of an object may be insufficient.

### Oxide Phosphor

The oxide phosphor contains Mg, Ga, O (oxygen), and Cr. The oxide phosphor has a composition that may optionally contain at least one first element M¹ selected from the group consisting of Ca, Sr, Ba, Ni, and Zn, at least one second element M² selected from the group consisting of B, Al, In, and Sc, and at least one third element M³ selected from the group consisting of Eu, Ce, Tb, Pr, Nd, Sm, Yb, Ho, Er, Tm, and Mn. When a total molar ratio of Ga, Cr, the second element M², and the third element M³ per mole of the composition of the oxide phosphor is 2, the molar ratio of Mg or the molar ratio of a total of Mg and the first element M¹ when the first element M¹ is included is in a range of 0.7 to 1.3. The molar ratio of O is within a range of 3.7 to 4.3, and the molar ratio of Cr is within a range greater than 0.02 and 0.3 or less. Further, when the molar ratio of a total of Mg and the first element M¹ is 1, the molar ratio of the first element M¹ is in a range of 0 to 0.8, the molar ratio of the second element M² is in a range of 0 to 1.6, the molar ratio of the third element M³ is in a range of 0 to 0.2, and the molar ratio of the third element M³ is smaller than the molar ratio of Cr. In a light emission spectrum as a phosphor, the oxide phosphor has a light emission peak wavelength in a range of 800 nm to 1600 nm. The first element M¹, the second element M², and the third element M³ may include two or more types of elements.

The oxide phosphor having a composition in which each element has the above-described molar ratio range is excited by absorbing light from a light source with a wavelength of 400 nm or greater, and emits light having a light emission peak wavelength in a range of 800 nm to 1600 nm. An oxide phosphor having a composition in which each element has the molar ratio range described above, for example, an oxide phosphor having a composition represented by the following Formula (1), has a high absorption rate of light in, for example, a wavelength range of ultraviolet light from 10 nm to 400 nm, and specifically, light in a wavelength range of 240 nm to 260 nm, as well as light in a wavelength range of 400 nm to 450 nm, and also absorbs light in a wavelength range of 400 nm to 450 nm, and emits light having a light emission peak wavelength in a range of 800 nm to 1600 nm. The oxide phosphor having a composition in which the molar ratio of each element is within the above-described ranges also has a high absorption rate of light in a wavelength range of 550 nm to 600 nm, and can be excited by absorbing light in the range of 550 nm to 600 nm.

The oxide phosphor preferably has a composition included in the compositional formula represented by Formula (1) below:

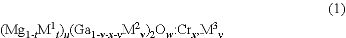

where in Formula (1), t, u, v, w, x, and y satisfy 0≤t≤0.8, 0.7≤u≤1.3, 0≤v≤0.8, 3.7≤w≤4.3, 0.02≤x≤0.3, 0≤y≤0.2, and y<x.

In the oxide phosphor, the first element M¹ preferably includes at least one element selected from the group consisting of Ca, Sr, Ni and Zn, the second element M² preferably includes at least one element selected from the group consisting of Al and Sc, and the third element M³ preferably includes at least one element selected from the group consisting of Eu, Ce, Ni, and Mn.

When the oxide phosphor has a composition included in the compositional formula represented by Formula (1), a variable u representing the molar ratio of Mg or the molar ratio of the total of Mg and the first element M¹ when the oxide phosphor contains the first element M¹ may satisfy 0.8≤u≤1.2, 0.9≤u≤1.1, or u=1.0. When the oxide phosphor has the composition represented by Formula (1), the molar ratio of the first element M¹ is represented by the product of a variable t and the variable u, and when the molar ratio of the total of Mg and the first element M¹ is 1, the variable t may satisfy 0.1≤t≤0.7, 0.2≤t≤0.6, or 0.3≤t≤0.5.

When the oxide phosphor contains Zn as the first element M¹, in a case in which the molar ratio of the total of the first element M¹ and Mg per mole of the composition of the oxide phosphor is 1, the molar ratio of the first element M¹ is preferably in a range of 0.1 to 0.5. When the oxide phosphor contains Zn as the first element M¹, in a case in which the molar ratio of the total of the first element M¹ and Mg per mole of the composition of the oxide phosphor is 1, preferably, the molar ratio of the first element M¹ is within the range of 0.1 to 0.5, and the oxide phosphor contains the second element M², and the second element M² is preferably Al. When the oxide phosphor contains Zn as the first element M¹ and Al as the second element M², in a case in which the oxide phosphor has a composition included in the compositional formula represented by Formula (1), and in Formula (1), the first element M¹ is Zn and the second element M² is Al, the variable t preferably satisfies 0.1≤t≤0.5, and the variable v preferably satisfies 0.1≤v≤0.6, and more preferably satisfies 0.2≤v≤0.5. When the oxide phosphor contains Zn as the first element M¹, in a case in which the molar ratio of the total of the first element M¹ and Mg in the composition of the oxide phosphor is 1, if the molar ratio of the first element M¹ is within the above range, the oxide phosphor has a light emission peak wavelength within a range of 800 nm to 1600 nm in the light emission spectrum.

When the oxide phosphor contains Ni as the first element M¹, in a case in which the molar ratio of the total of the first element M¹ and Mg per mole of the composition of the oxide phosphor is 1, the molar ratio of the first element M¹ is preferably in a range from 0.001 to 0.50, may be in a range from 0.002 to 0.30, and may be in a range from 0.005 to 0.20. When the oxide phosphor has a composition included in the compositional formula represented by Formula (1), and when the first element M¹ is Ni in Formula (1), the variable t preferably satisfies 0.001≤t≤0.50, may satisfy 0.002≤t≤0.30, or may satisfy 0.005≤t≤0.20. When the oxide phosphor contains Ni as the first element M¹, in a case in which the molar ratio of the total of the first element M¹ and Mg in the composition of the oxide phosphor is 1, if the molar ratio of the first element M¹ is within the above range, the oxide phosphor has a light emission peak wavelength within a range from 800 nm to 1600 nm in the light emission spectrum.

When the oxide phosphor has a composition included in the compositional formula represented by Formula (1), the molar ratio of the second element M² is represented by the product of the variable v and 2. The variable v in Formula (1) satisfies 0≤v≤0.8, may satisfy 0.01≤v≤0.70, may satisfy 0.02≤v≤0.60, and may satisfy 0.05≤v≤0.50.

When the total of Ga, Cr, the second element M², and the third element M³ per mole of the composition of the oxide phosphor is 2, the molar ratio of O (oxygen) contained in the oxide phosphor is in a range from 3.7 to 4.3, may be in a range from 3.8 to 4.2, may be in a range from 3.9 to 4.1, or may be 4.0. When the oxide phosphor has a composition included in the compositional formula represented by Formula (1), a variable w representing the molar ratio of O (oxygen) in Formula (1) may satisfy 3.7≤w≤4.3, may satisfy 3.8≤w≤4.2, may satisfy 3.9≤w≤4.1, or may be w=4.

In the oxide phosphor, Cr is an activating element. When the oxide phosphor has a composition included in the compositional formula represented by Formula (1), the molar ratio of Cr is represented by a variable x. The variable x in Formula (1) satisfies 0.02<x≤0.3, may satisfy 0.03≤x≤0.25, or may satisfy 0.03<x≤0.20.

In the oxide phosphor, the third element M³ is an activating element together with Cr. When the oxide phosphor has a composition included in the compositional formula represented by Formula (1), the molar ratio of the third element M³ is represented by a variable y. The variable y in Formula (1) satisfies 0≤y≤0.20, may satisfy 0.001≤y≤0.20, may satisfy 0.002≤y≤0.15, and may satisfy 0.003≤y≤0.10. In order to emit light having a target light emission peak wavelength, the molar ratio of the third element M³ in the composition of the oxide phosphor is smaller than the molar ratio of Cr. When the oxide phosphor has the composition represented by Formula (1), the variable x representing the molar ratio of Cr and the variable y representing the molar ratio of the third element M³ satisfy y<x.

Through irradiation with light from a light source, the oxide phosphor has a light emission peak wavelength in a range from 800 nm to 1600 nm in the light emission spectrum of the phosphor. When, through irradiation with light from a light source, the oxide phosphor has a light emission peak wavelength in the range from 800 nm to 1600 nm in the light emission spectrum of the phosphor, the increase or decrease of light in the range from 800 nm to 1300 nm and the quality of food products such as fruits and vegetables can be measured, and thus the oxide phosphor can be used in a light source that is used in a small analytical instruments for medical use or food product use. Through irradiation with light from a light source, the oxide phosphor may have, in a light emission spectrum of the phosphor, a light emission peak wavelength in a range from 810 nm to 1500 nm, a light emission peak wavelength in a range from 820 nm to 1400 nm, a light emission peak wavelength in a range from 820 nm to 1300 nm, a light emission peak wavelength in a range from 820 nm to 1200 nm, a light emission peak wavelength in a range from 830 nm to 1000 nm, or a light emission peak wavelength in a range from 830 nm to 980 nm.

In the light emission spectrum, the oxide phosphor has a light emission peak wavelength in a range from 800 nm to 1600 nm, and the full width at half maximum of the light emission spectrum is preferably in a range from 150 nm to 350 nm, may be in a range from 160 nm to 340 nm, or may be in a range from 170 nm to 330 nm. In the present specification, the full width at half maximum refers to a wavelength width at which the light emission intensity is 50% of the light emission intensity at the light emission peak wavelength showing the maximum light emission intensity in the light emission spectrum. Absorption and scattering of light occur in a living body, and in order to measure a subtle change in the propagation behavior of light in blood in the living body, light having a light emission peak with a wide full width at half maximum is preferably irradiated. In addition, even in a case in which food products such as fruits, vegetables, and rice are to be measured in a non-destructive manner, light having a light emission spectrum with a wide full width at half maximum is preferably irradiated in order to obtain information regarding the inside of the food product. In addition, regarding how the color of an object looks when irradiated with light (hereinafter, also referred to as a “color rendering property”), the light preferably has a light emission spectrum in a wide wavelength range, and with a wider full width at half maximum, light having an excellent color rendering property can be emitted. For example, even in a case of use in a place where work is performed, such as a factory, the emission of light that does not disturb the spectral balance of the light may be required such that a worker can easily perform the work.

When the oxide phosphor has, in the light emission spectrum, a light emission peak wavelength in the range from 800 nm to 1000 nm, the full width at half maximum of the light emission spectrum is preferably in a range from 150 nm to 250 nm, and is more preferably in a range from 160 nm to 240 nm. In the light emission spectrum of the oxide phosphor, the full width at half maximum of the light emission spectrum may be 160 nm or greater, 170 nm or greater, 180 nm or greater, or 190 nm or greater, and may be 250 nm or less, or 230 nm or less.

When the oxide phosphor has, in the light emission spectrum, a light emission peak wavelength in a range greater than 1000 nm and 1600 nm or less, for example, in a range from 1001 nm to 1600 nm, the full width at half maximum of the light emission spectrum is preferably in a range from 150 nm to 350 nm, more preferably in a range from 180 nm to 340 nm, even more preferably in a range from 200 nm to 330 nm, and yet even more preferably in a range from 205 nm to 330 nm.

The cumulative 50% median particle size (median size) Dm of the oxide phosphor in a volume-based particle size distribution measured by a laser diffraction particle size distribution measurement method is preferably in a range from 5 μm to 50 μm, and is more preferably in a range from 10 μm to 30 μm. When the median particle size of the oxide phosphor is in the range from 5 μm to 50 μm, the oxide phosphor easily absorbs excitation light, and easily emits light having a light emission peak wavelength in the range from 800 nm to 1600 nm in the light emission spectrum. The median size Dm can be measured using, for example, a laser diffraction-type particle size measuring device (MASTER SIZER 3000, available from Malvern Instruments Ltd.).

### Light-Emitting Device

The light-emitting device is provided with the oxide phosphor and a light-emitting element having a light emission peak wavelength in a range from 365 nm to 500 nm and irradiates the oxide phosphor. The oxide phosphor can be used as a member constituting a wavelength conversion member together with a light-transmissive material.

The light-emitting device is preferably provided with, for example, an LED chip or an LD chip in which a nitride-based semiconductor is used as a light-emitting element for irradiating the oxide phosphor.

The light-emitting element has a light emission peak wavelength in a range from 365 nm to 500 nm, preferably has a light emission peak wavelength in a range from 370 nm to 490 nm, more preferably has a light emission peak wavelength in a range from 375 nm to 480 nm, and even more preferably has a light emission peak wavelength in a range from 380 nm to 470 nm. Through the use of a light-emitting element as an excitation light source for the oxide phosphor, a light-emitting device that emits mixed color light of a desired wavelength range, the mixed color light including light from the light-emitting element and fluorescent light from phosphors including the oxide phosphor, can be configured. The full width at half maximum of the light emission peak in the light emission spectrum of the light-emitting element may be, for example, 30 nm or less. As the light-emitting element, for example, a light-emitting element that uses a nitride-based semiconductor is preferably used. A stable light-emitting device that exhibits high efficiency and high output linearity with respect to an input and that is strong against mechanical impact can be obtained by using, as a light source, a light-emitting element in which a nitride-based semiconductor is used.

The light-emitting device includes, as an essential component, a first phosphor including the oxide phosphor described above, and may further include a different phosphor. In addition to the first phosphor, the light-emitting device preferably includes at least one phosphor selected from the group consisting of a second phosphor having a light emission peak wavelength in a range from 455 nm to less than 495 nm, a third phosphor having a light emission peak wavelength in a range from 495 nm to less than 610 nm, a fourth phosphor having a light emission peak wavelength in a range from 610 nm to less than 700 nm, and a fifth phosphor having a light emission peak wavelength in a range from 700 nm to 1050 nm, the light emission peak wavelengths being within the light emission spectrum of each phosphor. The light-emitting device more preferably includes the first phosphor including the oxide phosphor described above as an essential component, and at least one phosphor selected from the group consisting of the third phosphor, the fourth phosphor, and the fifth phosphor. Further, the light-emitting device preferably has a light emission spectrum that is continuous in a range from the light emission peak wavelength of the light-emitting element to 900 nm, and in which on the basis of a maximum light emission intensity in the range from the light emission peak wavelength of the light-emitting element to 900 nm being 100%, a minimum light emission intensity in the range from the light emission peak wavelength of the light-emitting element to 900 nm is 3% or higher. The light emission spectrum of the light-emitting device being continuous in the range from the light emission peak wavelength of the light-emitting element to 900 nm means that in the entire wavelength range from the light emission peak wavelength of the light-emitting element to 900 nm, the light emission spectrum is continuous without the light emission intensity of the light emission spectrum becoming 0% and without the light emission spectrum being interrupted. A light source that emits light having a light emission spectrum in a wavelength range including from visible light to a portion of near-infrared light may be required depending on the measurement target or detection target such as in a living body or a fruit or vegetable. When a tungsten lamp or a xenon lamp is used as a light source, light having a continuous light emission spectrum from visible light to a wavelength range including a portion of near-infrared light is emitted without interruption of the light emission spectrum. However, when a tungsten lamp or a xenon lamp is used as the light source, it is difficult to reduce the size of the device. Further, with a light-emitting device that emits light for which the light emission spectrum is continuous within a range from the light emission peak wavelength of the light-emitting element to 900 nm, and for which on the basis of a maximum light emission intensity in the range from the light emission peak wavelength of the light-emitting element to 900 nm being 100%, a minimum light emission intensity in the range from the light emission peak wavelength of the light-emitting element to 900 nm is 3% or higher, the light-emitting device can emit, from the light source, light having a light emission spectrum within a range from visible light to a wavelength including a portion of infrared light. Such a light-emitting device can be made smaller than a light-emitting device in which a tungsten lamp or a xenon lamp is used as a light source. Further, such a small light-emitting device can be mounted on a small mobile device such as a smartphone, and can be used for physical condition management or the like when information on the inside of a living body is obtained. Here, “within a range from the light emission peak wavelength of the light-emitting element to 900 nm” means, for example, within a range from 443 nm to 900 nm when the light emission peak wavelength of the light-emitting element is 443 nm.

The light-emitting device has a light emission spectrum that is continuous in the range from the light emission peak wavelength of the light-emitting element to 900 nm, and in which on the basis of a maximum light emission intensity in the range from the light emission peak wavelength of the light-emitting element to 900 nm being 100%, a minimum light emission intensity in the range from the light emission peak wavelength of the light-emitting element to 900 nm is 3% or higher, and the light-emitting device emits light in a wide wavelength range from visible light to near infrared light. Such a light-emitting device can be used, for example, in a reflection spectroscopic measurement device or in an illumination device that can measure inside a living body, fruits and vegetables, or the like in a non-destructive manner and requires light having excellent color rendering properties.

The second phosphor, which has a different composition than the first phosphor including the oxide phosphor described above, preferably includes at least one type of phosphor selected from the group consisting of a phosphate phosphor having a composition represented by Formula (2a) below, an aluminate phosphor having a composition included in a compositional formula represented by Formula (2b) below, and an aluminate phosphor having a composition represented by Formula (2c) below, and the second phosphor may include two or more types of phosphors:

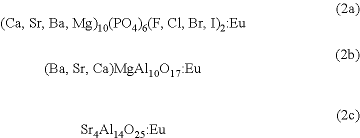

In the present specification, a plurality of elements separated by commas (,) in a compositional formula means that at least one element among the plurality of elements is contained in the composition. Also, herein, in a compositional formula representing a composition of a phosphor, information preceding the colon (:) represents elements configuring a host crystal and the molar ratio thereof, and information following the colon (:) represents an activating element.

The third phosphor preferably includes at least one type of phosphor selected from the group consisting of a silicate phosphor having a composition represented by Formula (3a) below, an aluminate phosphor or a gallate phosphor having a composition represented by Formula (3b) below, a β-sialon phosphor having a composition represented by Formula (3c) below, a cesium-lead halide phosphor having a composition represented by Formula (3d) below, and a nitride phosphor having a composition represented by formula (3e) below, and the third phosphor may include two or more types of phosphors. In a case in which the third phosphor includes two or more types of phosphors, the two or more types of third phosphors are preferably phosphors having light emission peak wavelengths in respectively different ranges within a range from 495 nm to 610 nm.

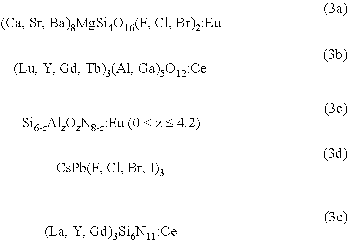

The fourth phosphor preferably includes at least one type of phosphor selected from the group consisting of a nitride phosphor having a composition represented by Formula (4a) below, a fluorogermanate phosphor having a composition represented by Formula (4b) below, an oxynitride phosphor having a composition represented by Formula (4c) below, a fluoride phosphor having a composition represented by Formula (4d) below, a fluoride phosphor having a composition represented by Formula (4e) below, a nitride phosphor having a composition represented by Formula (4f) below, and a nitride phosphor having a composition represented by Formula (4g) below, and the fourth phosphor may include two or more types of phosphors. When the fourth phosphor includes two or more types of phosphors, the two or more types of fourth phosphors are preferably phosphors having light emission peak wavelengths in respectively different ranges within a range from 610 nm to 700 nm.

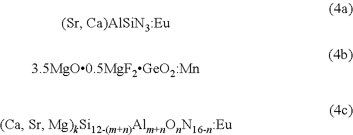

where in Formula (4c), k, m, and n satisfy 0<k≤2.0, 2.0≤m≤6.0, and 0≤n≤2.0.

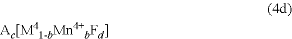

where in Formula (4d), A includes at least one ion selected from the group consisting of K⁺, Li⁺, Na⁺, Rb⁺, Cs⁺, and NH₄⁺, and among these, K⁺ is preferable. M⁴ includes at least one element selected from the group consisting of group 4 elements and group 14 elements, and among these, Si and Ge are preferable. b satisfies 0<b<0.2, c is an absolute value of the electric charge of the [M⁴_{1-b}M⁴⁺_{b}F_{d}] ion, and d satisfies 5<d<7.

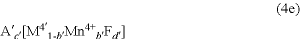

where in Formula (4e), A′ includes at least one ion selected from the group consisting of K⁺, Li⁺, Na⁺, Rb⁺, Cs⁺, and NH₄⁺, and among these, K⁺ is preferable. M^{4′} contains at least one element selected from the group consisting of group 4 elements, group 13 elements, and group 14 elements, and among these, Si and Al are preferable. b′ satisfies 0<b><0.2, c′ is an absolute value of the electric charge of the [M⁴_{1-b′}Mn⁴⁺_{b′}Fa_{d′}] ion, and d′ satisfies 5<d′<7.)

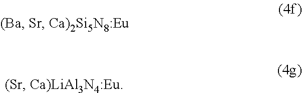

The fifth phosphor preferably includes at least one phosphor selected from the group consisting of a gallate phosphor having a compositional formula represented by Formula (5a) below, an aluminate phosphor having a compositional formula represented by Formula (5b) below, a gallate phosphor having a compositional formula represented by Formula (5c) below, an aluminate phosphor having a composition represented by Formula (5d) below, and a phosphor having a composition represented by Formula (5e) below, and the fifth phosphor may include two or more types of phosphors. The disclosure of JP 2020-198326 can be referenced for information regarding the phosphor having a composition included in the compositional formula represented by Formula (5e) below.

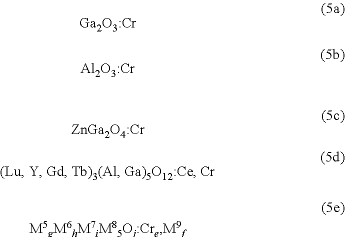

where in Formula (5e), M⁵ is at least one element selected from the group consisting of Li, Na, Ka, Rb and Cs, M⁶ is at least one element selected from the group consisting of Mg, Ca, Sr, Ba and Zn, M⁷ is at least one element selected from the group consisting of Ba, Al, Ga, In and rare earth elements, M⁸ is at least one element selected from the group consisting of Si, Ti, Ge, Zr, Sn, Hf and Pb, and M⁹ is at least one element selected from the group consisting of Eu, Ce, Tb, Pr, Nd, Sm, Yb, Ho, Er, Tm, Ni and Mn, and e, f, g, h, i, and j satisfy 0<e≤0.2, 0≤f≤0.1, f<e, 0.7≤g≤1.3, 1.5≤h≤2.5, 0.7≤i≤1.3, and 12.9≤j≤15.1.

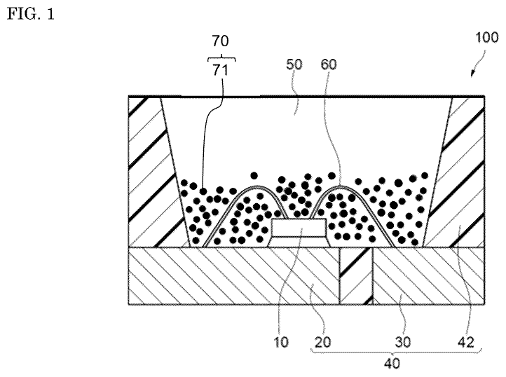

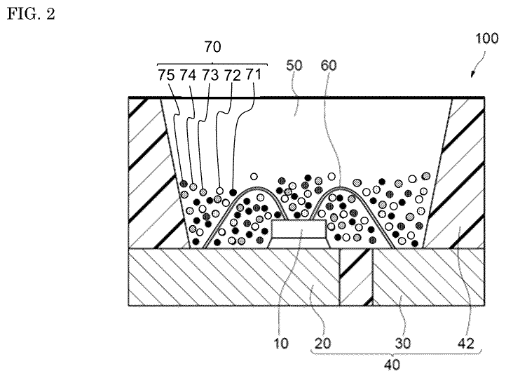

An example of the light-emitting device will be described on the basis of the drawings. FIG. 1 is a schematic cross-sectional view illustrating one example of first configurational example of a light-emitting device. FIG. 2 is a schematic cross-sectional view illustrating another example of the first configurational example of the light-emitting device.

As illustrated in FIG. 1, a light-emitting device 100 includes a molded body 40 having a recess, a light-emitting element 10 serving as a light source, and a wavelength conversion member 50 covering the light-emitting element 10. The molded body 40 is formed by integrally molding a first lead 20, a second lead 30, and a resin portion 42 including a thermoplastic resin or a thermosetting resin. In the molded body 40, the first lead 20 and the second lead 30 configuring the bottom surface of the recess are arranged, and the resin portion 42 configuring the side surfaces of the recess is arranged. The light-emitting element 10 is mounted on the bottom surface of the recess of the molded body 40. The light-emitting element 10 includes a pair of positive and negative electrodes, and the pair of the positive and negative electrodes are electrically connected to the first lead 20 and the second lead 30 through respective via wires 60. The light-emitting element 10 is covered by the wavelength conversion member 50. The wavelength conversion member 50 includes a phosphor 70 that subjects the light-emitting element 10 to wavelength conversion, and a light-transmissive material. The phosphor 70 includes, as an essential component, a first phosphor 71 including an oxide phosphor. The phosphor 70 may include a phosphor having a light emission peak wavelength in a wavelength range different from the light emission peak wavelength of the first phosphor 71. As illustrated in FIG. 2, the phosphor 70 preferably includes at least one type of phosphor selected from the group consisting of a second phosphor 72, a third phosphor 73, a fourth phosphor 74, and a fifth phosphor 75, which are each described above, and may include two or more types of phosphors. The phosphor 70 includes the first phosphor 71 as an essential component, and may include the second phosphor 72, the third phosphor 73, the fourth phosphor 74, and the fifth phosphor 75. The wavelength conversion member 50 also functions as a member for protecting the light-emitting element 10 and the phosphor 70 from the external environment. The light-emitting device 100 receives a supply of power from the outside via the first lead 20 and the second lead 30, and thereby emits light.

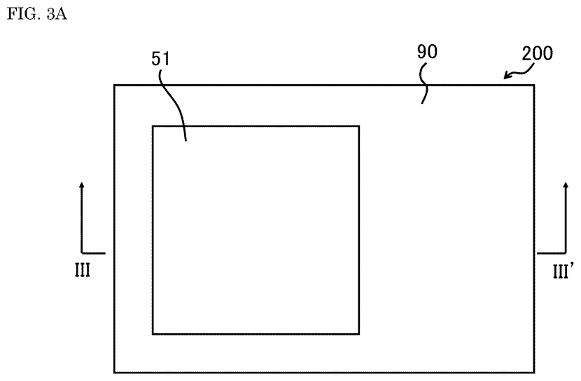

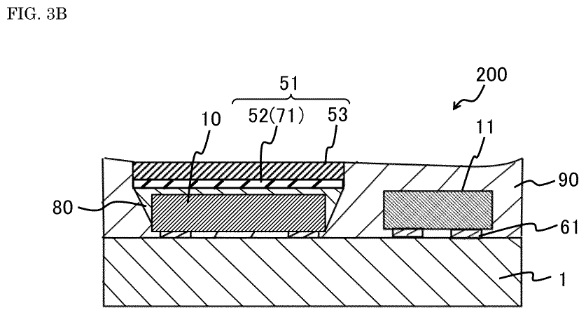

FIGS. 3A and 3B illustrate a second configurational example of a light-emitting device. FIG. 3A is a schematic cross-sectional view of a light-emitting device 200. FIG. 3B is a schematic cross-sectional view along line III-III′ of a light-emitting device 200 illustrated in FIG. 3A. The light-emitting device 200 is provided with: a light-emitting element 10 having a light emission peak wavelength in a range from 365 nm to 500 nm; and a wavelength conversion member 51 including a wavelength conversion body 52 that includes a first phosphor 71 that emits light when excited by light from the light-emitting element 10, and a light-transmissive body 53 on which the wavelength conversion body 52 is disposed. The light-emitting element 10 is flip-chip mounted on a substrate 1 via a bump, which is a conductive member 61. The wavelength conversion body 52 of the wavelength conversion member 51 is provided on the light-emitting surface of the light-emitting element 10 via an adhesive layer 80. The lateral surfaces of the light-emitting element 10 and the wavelength conversion member 52 are covered with a cover member 90 that reflects light. The wavelength conversion body 52 is excited by light from the light-emitting element 10 and includes, as an essential component, the first phosphor 71 including an oxide phosphor. The wavelength conversion body 52 may include at least one phosphor selected from the group consisting of the second phosphor, the third phosphor, the fourth phosphor, and the fifth phosphor. The light-emitting element 10 receives a supply of electric power from outside of the light-emitting device 200 through the conductive member 61 and wiring formed on the substrate 1, and can cause the light-emitting device 200 to emit light. The light-emitting device 200 may include a semiconductor element 11 such as a protective element for preventing the light-emitting element 10 from being damaged by the application of excessive voltage. The cover member 90 is provided so as to cover the semiconductor element 11, for example. Each of the members used in the light-emitting device will be described below. For details, reference may be made to the disclosure of JP 2014-112635 A, for example.

Examples of the light-transmissive material constituting the wavelength conversion member together with the phosphor include at least one material selected from the group consisting of resins, glass, and inorganic substances. As the resin, at least one type of resin selected from the group consisting of silicone resin, epoxy resin, phenol resin, polycarbonate resin, acrylic resin, and modified resins thereof can be used. The silicone resin and the modified silicone resin are preferable in terms of exhibiting excellent heat resistance and light resistance. The wavelength conversion member may contain, in addition to the phosphor and the light-transmissive material, a filler, a coloring agent, and a light diffusing material, as necessary. Examples of the filler include silicon oxide, barium titanate, titanium oxide, an aluminum oxide.

In a case in which the wavelength conversion member contains a resin and a phosphor, preferably, a wavelength conversion member-forming composition containing the phosphor in the resin is formed, and the wavelength conversion member-forming composition is used to form the wavelength conversion member. In the wavelength conversion member-forming composition, per 100 parts by mass of the resin, the content of the first phosphor including the oxide phosphor is preferably in a range from 20 parts by mass to 100 parts by mass, may be in a range from 25 parts by mass to 90 parts by mass, and may be in a range from 30 parts by mass to 85 parts by mass. The first phosphor may include only the oxide phosphor. The oxide phosphor contained in the first phosphor may include two or more types of oxide phosphors having different compositions.

The wavelength conversion member-forming composition is adjusted such that the content of each phosphor is within the ranges described below.

The content of the second phosphor contained in the wavelength conversion member-forming composition may be, per 100 parts by mass of resin, in a range from 10 parts by mass to 100 parts by mass, in a range from 20 parts by mass to 90 parts by mass, or in a range from 30 parts by mass to 80 parts by mass.

The content of the third phosphor contained in the wavelength conversion member-forming composition may be, per 100 parts by mass of the resin, in a range from 5 parts by mass to 100 parts by mass, in a range from 10 parts by mass to 90 parts by mass, in a range from 15 parts by mass to 80 parts by mass, in a range from 20 parts by mass to 70 parts by mass, or in a range from 25 parts by mass to 60 parts by mass.

The content of the fourth phosphor contained in the wavelength conversion member-forming composition may be, per 100 parts by mass of resin, in a range from 1 part by mass to 50 parts by mass, in a range from 2 parts by mass to 40 parts by mass, in a range from 3 parts by mass to 30 parts by mass, in a range from 4 parts by mass to 40 parts by mass, or in a range from 5 parts by mass to 20 parts by mass.

The content of the fifth phosphor contained in the wavelength conversion member-forming composition may be, per 100 parts by mass of resin, in a range from 5 parts by mass to 100 parts by mass, in a range from 10 parts by mass to 90 parts by mass, in a range from 10 parts by mass to 80 parts by mass, or in a range from 15 parts by mass to 70 parts by mass. In a case in which the wavelength conversion member-forming composition contains the fifth phosphor and the fifth phosphor contains two or more types of phosphors, the content of the fifth phosphor refers to the total content of the two or more types of fifth phosphors. In a case in which the wavelength conversion member-forming composition contains two or more types of any phosphors of the second phosphor to the fourth phosphor, the content refers to the total content of the two or more types of phosphors.

The total content of the phosphors contained in the wavelength conversion member-forming composition may be, per 100 parts by mass of the resin, in a range from 50 parts by mass to 300 parts by mass, in a range from 100 parts by mass to 280 parts by mass, in a range from 120 parts by mass to 250 parts by mass, or in a range from 150 parts by mass to 200 parts by mass.

The wavelength conversion member may be further provided with a light-transmissive body. A plate-shape body made of a light-transmissive material such as glass or resin can be used as the light-transmissive body. Examples of the glass include borosilicate glass and quartz glass. Examples of the resin include a silicone resin and an epoxy resin. When the wavelength conversion member includes a substrate, the substrate is preferably made of an insulating material that does not easily transmit light from the light-emitting element or external light. Examples of the material of the substrate include ceramics such as aluminum oxide and aluminum nitride, and resins such as phenol resin, epoxy resin, polyimide resin, bismaleimide triazine resin (BT resin), and polyphthalamide (PPA) resin. When an adhesive layer is interposed between the light-emitting element and the wavelength conversion member, the adhesive constituting the adhesive layer is preferably made of a material that can optically couple the light-emitting element and the wavelength conversion member. The material constituting the adhesive layer is preferably at least one type of resin selected from the group consisting of epoxy resin, silicone resin, phenol resin, and polyimide resin.

Examples of the semiconductor element provided as necessary in the light-emitting device include a transistor for controlling the light-emitting element and a protective element for suppressing damage or performance deterioration of the light-emitting element due to the application of excessive voltage. An example of the protective element is a Zener diode. When the light-emitting device is provided with a cover member, an insulating material is preferably used as the material of the cover member. More specific examples of the material of the cover member include phenol resin, epoxy resin, bismaleimide triazine resin (BT resin), polyphthalamide (PPA) resin, and silicone resin. A coloring agent, a phosphor, or a filler may be added to the cover member, as necessary. The light-emitting device may use a bump as the conductive member. Au or an Au alloy can be used as the material of the bump, and eutectic solder (Au−Sn), Pb−Sn, lead-free solder, or the like can be used as the other conductive member.

### Method for Manufacturing Light-Emitting Device

An example of a method for manufacturing a light-emitting device according to a first configurational example will be described. For details, reference may be made to the disclosure of JP 2010-062272 A, for example. The method for manufacturing the light-emitting device preferably includes a step of preparing a molded body, a step of disposing a light-emitting element, a step of disposing a composition for forming a wavelength conversion member, and a step of forming a resin package. When an aggregate molded body having a plurality of recesses is used as the molded body, the manufacturing method may include, after the resin package formation step, a singulation step of separating each resin packages of each unit region.

In the step of preparing a molded body, a plurality of leads are integrally molded using a thermosetting resin or a thermoplastic resin to prepare a molded body having a recess with side surfaces and a bottom surface. The molded body may be a molded body composed of an aggregate substrate including a plurality of recesses.

In the step of disposing the light-emitting element, the light-emitting element is disposed on the bottom surface of the recess of the molded body, and the positive and negative electrodes of the light-emitting element are connected to the first lead and the second lead by wires. In the step of disposing the wavelength conversion member-forming composition, the wavelength conversion member-forming composition is disposed in the recess of the molded body.

In the resin package forming step, the wavelength conversion member-forming composition disposed in the recess of the molded body is cured to form the resin package, and thereby the light-emitting device is manufactured. When a molded body composed of an aggregate base including a plurality of recesses is used, after the resin package forming step, the aggregate base including the plurality of recesses is separated into each resin package in each unit region in the singulation step, and individual light-emitting devices are manufactured. In this manner, the light-emitting device illustrated in FIG. 1 or FIG. 2 can be manufactured.

An example of a method for manufacturing a light-emitting device according to a second configurational example will be described. For details, reference may be made to the disclosure of JP 2014-112635 A or JP 2017-117912 A, for example. The method for manufacturing the light-emitting device preferably includes a step of disposing a light-emitting element, a step of disposing a semiconductor element as necessary, a step of forming a wavelength conversion member including a wavelength conversion body, a step of adhering the light-emitting element and the wavelength conversion member, and a step of forming a cover member.

For example, in the step of disposing the light-emitting element, the light-emitting element is disposed on a substrate. The light-emitting element and the semiconductor element are, for example, flip chip mounted on the substrate. Subsequently, in the step of forming the wavelength conversion member including the wavelength conversion body, the wavelength conversion body may be obtained by forming a plate-shaped, sheet-shaped, or layer-shaped wavelength conversion body on one surface of a light-transmissive body by a printing method, an adhesion method, a compression molding method, or an electrodeposition method. For example, the printing method can be used to form a wavelength conversion member containing a wavelength conversion body by printing a wavelength conversion body composition including a phosphor and a resin serving as a binder or a solvent on one surface of a light-transmissive body. Subsequently, in the step of adhering the light-emitting element and the wavelength conversion member to each other, the wavelength conversion member is bonded on the light-emitting element through an adhesive layer with the wavelength conversion member facing the light-emitting surface of the light-emitting element. Subsequently, in the step of forming the cover member, the lateral surfaces of the light-emitting element and the wavelength conversion member are covered with the cover member composition. The cover member reflects light emitted from the light-emitting element, and is preferably formed such that when the light-emitting device also includes a semiconductor element, the semiconductor element is embedded in the cover member. In this manner, the light-emitting device illustrated in FIG. 3A and FIG. 3B can be manufactured.

### Oxide Phosphor Production Method

The method for producing an oxide phosphor includes: preparing a first compound containing Mg, a second compound containing Ga, a third compound containing Cr, and optionally, a fourth compound containing at least one first element M¹ selected from the group consisting of Ca, Sr, Ba, Ni, and Zn, a fifth compound containing at least one second element M² selected from the group consisting of B, Al, In, and Sc, and a sixth compound containing at least one third element M³ selected from the group consisting of Eu, Ce, Tb, Pr, Nd, Sm, Yb, Ho, Er, Tm, and Mn; preparing a raw material mixture including the first compound, the second compound, the third compound, and optionally, the fourth compound, the fifth compound, or the sixth compound that have been adjusted and mixed such that when a total molar ratio of Ga, Cr, the second element M², and the third element M³ per mole of the composition of the oxide phosphor is 2, a molar ratio of Mg or a molar ratio of a total of Mg and the first element M¹ when the first element M¹ is included is in a range from 0.7 to 1.3, a molar ratio of Cr is in a range greater than 0.02 and 0.3 or less, when a molar ratio of a total of Mg and the first element M¹ is 1, a molar ratio of the first element M¹ is in a range from 0 to 0.8, a molar ratio of the second element M² is in a range from 0 to 1.6, a molar ratio of the third element M³ is in a range from 0 to 0.2, and the molar ratio of the third element M³ is smaller than the molar ratio of Cr; and obtaining an oxide phosphor by heat-treating the raw material mixture in an atmosphere containing oxygen at a temperature in a range from 1200° C. to 1700° C., in which at least one selected from the group consisting of the first compound, the second compound, and the third compound is an oxide.

### Raw Material Mixture Preparation Step

### Raw Materials

As the raw materials for producing the oxide phosphor, examples of the first compound containing Mg, the second compound containing Ga, the third compound containing Cr, and optionally, the fourth compound containing the first element M¹, the fifth compound containing the second element M², and the sixth compound containing the third element M³ include oxides, carbonates, chlorides, hydrates thereof. At least one compound selected from the group consisting of the first compound, the second compound, and the third compound is an oxide, and two or more of these compounds may be oxides. The third compound containing the first element M¹, the fifth compound containing the second element M², or the sixth compound containing the third element M³, which are contained as necessary, may be an oxide. The first compound, the second compound, the third compound, the fourth compound, the fifth compound, and the sixth compound are preferably powders.

Specific examples of the first compound include MgO, MgCO₃, MgCl₂, and hydrates thereof. Specific examples of the second compound include Ga₂O₃, GaCl₂, and GaCl₃. Specific examples of the third compound include Cr₂O₃, Cr₂(CO₃)₃, CrCl₂, and CrCl₃. Examples of the fourth compound, the fifth compound, and the sixth compound include oxides containing the first element M¹, the second element M², or the third element M³, or compounds that are stable as a compound and easily become an oxide. Specific examples include CaCO₃, CaO, SrCO₃, SrO, BaCO₃, NiO, NiCO₃, ZnO, B₂O₃, Al₂O₃, In₂O₃, Sc₂O₃, Eu₂O₃, Ce₂O₃, CeO₂, Ce₂(CO₃)₃, Tb₄O₇, Pr₆O₁₁, Pr₂(CO₃)₃, Nd₂O₃, Nd₂(CO₃)₃, Sm₂O₃, Sm₂(CO₃)₃, Yb₂O₃, Ho₂O₃, Er₂O₃, Tm₂O₃, MnO, Mn₂O₃, MnO₄ and Mn₃O₄. The first compound, the second compound, the third compound, the fourth compound, the fifth compound, and the sixth compound may be hydrates.

### Raw Material Mixture

A raw material mixture is obtained by weighing and mixing each compound serving as a raw material including the first compound containing Mg, the second compound containing Ga, the third compound containing Cr, and optionally, the fourth compound containing the first element M¹, the fifth compound containing the second element M², and the sixth compound containing the third element M³, such that when a total molar ratio of Ga, Cr, the second element M², and the third element M³ per mole of the composition of the oxide phosphor to be obtained is 2, the molar ratio of Mg or the molar ratio of the total of Mg and the first element M¹ when the first element M¹ is included is in a range from 0.7 to 1.3, the molar ratio of Cr is in a range greater than 0.02 and 0.3 or less, when a molar ratio of the total of Mg and the first element M¹ is 1, the molar ratio of the first element M¹ is in a range from 0 to 0.8, the molar ratio of the second element M² is in a range from 0 to 1.6, the molar ratio of the third element M³ is in a range from 0 to 0.2, and the molar ratio of the third element M³ is smaller than the molar ratio of Cr. Each of the weighed compounds may be wet- or dry-mixed, and may be mixed using a mixer. As a mixer, in addition to a ball mill commonly used in industrial applications, a vibration mill, a roll mill, a jet mill, or the like can be used.

Preferably, the raw material mixture containing each of the weighed compounds serving as raw materials is prepared so as to have a composition in which Mg, Ga, and Cr, and optionally, the first element M¹, the second element M², or the third element M³ contained in the respective compounds are included according to the compositional formula represented by Formula (1).

### Flux

The raw material mixture may include flux. When the raw material mixture includes a flux, the reaction between the raw materials is further promoted and the solid-phase reaction proceeds more uniformly, and thereby a phosphor having a large particle size and more excellent light-emitting characteristics can be obtained. When the heat treatment temperature for obtaining the phosphor is substantially equivalent to the temperature at which the liquid phase of the compound used as the flux is formed, the reaction between the raw materials is promoted by the flux. As the flux, a halide containing at least one element selected from the group consisting of rare earth elements, alkaline earth metal elements, and alkali metal elements can be used. Among halides, a fluoride can be used as the flux. When the element contained in the flux is the same element as at least some of the elements constituting the oxide phosphor, the flux can be added as a portion of the raw materials of the oxide phosphor having the targeted composition such that the composition of the oxide phosphor becomes the targeted composition, or the flux can be further added after the raw materials are mixed so as to form the target composition.

### Step of Obtaining Oxide Phosphor by Heat Treatment

The raw material mixture can be placed in a crucible or a boat made of a carbon such as graphite or of a material such as boron nitride (BN), alumina (Al₂O₃), tungsten (W), or molybdenum (Mo), and then heat-treated in a furnace.

### Heat Treatment Atmosphere

Heat treatment is preferably performed in an atmosphere containing oxygen. The oxygen content in the atmosphere is not particularly limited. The oxygen content in the atmosphere containing oxygen is preferably 5 vol % or greater, more preferably 10 vol % or greater, and even more preferably 15 vol % or greater. Heat treatment is preferably performed in an air atmosphere (oxygen content of 20 vol % or greater). When the atmosphere does not contain oxygen, that is, the oxygen content is less than 1 vol %, an oxide phosphor having a desired composition may not be obtained in some cases.

### Heat Treatment Temperature

A temperature for heat treatment is in a range from 1200° C. to 1700° C., preferably in a range from 1250° C. to 1650° C., and more preferably in a range from 1300° C. to 1600° C. When the heat treatment temperature is in the range from 1200° C. to 1700° C., decomposition due to heat is suppressed, and an oxide phosphor having the targeted composition and a stable crystal structure is obtained.

In the heat treatment, a retention time at a predetermined temperature may be provided. The retention time may be, for example, in a range from 0.5 hours to 48 hours, in a range from 1 hour to 40 hours, or in a range from 2 hours to 30 hours. Crystal growth can be promoted by setting the retention time to within a range from 0.5 hours to 48 hours.

The pressure of the heat treatment atmosphere may be standard atmospheric pressure (0.101 MPa), may be 0.101 MPa or higher, or may be a pressurized atmosphere in a range from 0.11 MPa to 200 MPa. In a case in which the heat treatment temperature is high, the crystal structure of the heat-treated product obtained by the heat treatment easily degrades. However, degradation of the crystal structure can be suppressed by performing the heat treatment in a pressurized atmosphere.

The heat treatment time can be appropriately selected according to the heat treatment temperature and the pressure of the atmosphere during the heat treatment, and is preferably in a range from 0.5 hours to 20 hours. Even in a case in which heat treatment is performed in two or more stages, the heat treatment time for one stage is preferably in a range from 0.5 hours to 20 hours. When the heat treatment time is in the range from 0.5 hours to 20 hours, degradation of the obtained heat-treated product is suppressed, and a phosphor having a stable crystal structure and a desired light emission intensity can be obtained. In addition, production costs can be reduced, and the production time can be relatively shortened. The heat treatment time is more preferably in a range from 1 hour to 10 hours, and even more preferably in a range from 1.5 hours to 9 hours.

The heat-treated product obtained by the heat treatment may be subjected to a post-treatment such as pulverization, dispersion, solid-liquid separation, and drying. Solid-liquid separation can be implemented by a method commonly used in industrial applications, such as filtration, suction filtration, pressure filtration, centrifugal separation, and decantation. Drying can be implemented using a device commonly used in industrial applications, such as a vacuum dryer, a hot air heating dryer, a conical dryer, or a rotary evaporator.

### EXAMPLES

The present invention will be described in detail hereinafter using examples. However, the present invention is not limited to these examples.

### Oxide Phosphor

### Example 1

Raw materials were weighed to include 8.44 g of MgCO₃, 18.28 g of Ga₂O₃ and 0.38 g of Cr₂O₃. Each element per mole of the composition of the obtained oxide phosphor was weighed such that the molar ratio of each element in the prepared composition was MgGa_{1.95}O₄:Cr_{0.05}. In the prepared composition, the molar ratio of elements whose molar ratio is not described was 1. The raw materials were mixed for 10 minutes using an agate mortar and an agate pestle to obtain a raw material mixture. The obtained raw material mixture was placed in an alumina crucible and heat-treated at 1400° C. in an air atmosphere (20 vol % of oxygen) at standard atmospheric pressure (0.101 MPa) for 6 hours. After the heat treatment, the obtained heat-treated product was pulverized, and an oxide phosphor of Example 1 was obtained.

### Example 2

Raw materials were weighed to include 8.44 g of MgCO₃, 18.09 g of Ga₂O₃, and 0.53 g of Cr₂O₃.

An oxide phosphor of Example 2 was obtained in the same manner as in Example 1 with the exception that a raw material mixture weighed such that the molar ratio of each element in the prepared composition was MgGa_{1.93}O₄:Cr_{0.07} was used.

### Example 3

Raw materials were weighed to include 8.44 g of MgCO₃, 17.91 g of Ga₂O₃, and 0.68 g of Cr₂O₃. An oxide phosphor of Example 3 was obtained in the same manner as in Example 1 with the exception that a raw material mixture weighed such that the molar ratio of each element in the prepared composition was MgGa_{1.91}O₄:Cr_{0.09} was used.

### Example 4

Raw materials were weighed to include 8.44 g of MgCO₃, 17.81 g of Ga₂O₃, and 0.76 g of Cr₂O₃. An oxide phosphor of Example 4 was obtained in the same manner as in Example 1 with the exception that a raw material mixture weighed such that the molar ratio of each element in the prepared composition was MgGa_{1.90}O₄:Cr_{0.10} was used.

### Example 5

Raw materials were weighed to include 8.44 g of MgCO₃, 18.47 g of Ga₂O₃, and 0.23 g of Cr₂O₃. An oxide phosphor of Example 5 was obtained in the same manner as in Example 1 with the exception that a raw material mixture weighed such that the molar ratio of each element in the prepared composition was MgGa_{1.97}O₄:Cr_{0.03} was used.

### Example 6

Raw materials were weighed to include 8.44 g of MgCO₃, 17.34 g of Ga₂O₃, and 1.14 g of Cr₂O₃. An oxide phosphor of Example 6 was obtained in the same manner as in Example 1 with the exception that a raw material mixture weighed such that the molar ratio of each element in the prepared composition was MgGa_{1.85}O₄:Cr_{0.15} was used.

### Example 7

Raw materials were weighed to include 8.44 g of MgCO₃, 16.87 g of Ga₂O₃, and 1.52 g of Cr₂O₃. An oxide phosphor of Example 7 was obtained in the same manner as in Example 1 with the exception that a raw material mixture weighed such that the molar ratio of each element in the prepared composition was MgGa_{1.80}O₄:Cr_{0.20} was used.

### Example 8

Raw materials were weighed to include 8.44 g of MgCO₃, 16.40 g of Ga₂O₃, and 1.90 g of Cr₂O₃. An oxide phosphor of Example 8 was obtained in the same manner as in Example 1 with the exception that a raw material mixture weighed such that the molar ratio of each element in the prepared composition was MgGa_{1.75}O₄:Cr_{0.25} was used.

### Example 9

Raw materials were weighed to include 8.44 g of MgCO₃, 15.94 g of Ga₂O₃, and 2.28 g of Cr₂O₃. An oxide phosphor of Example 9 was obtained in the same manner as in Example 1 with the exception that a raw material mixture weighed such that the molar ratio of each element in the prepared composition was MgGa_{1.70}O₄:Cr_{0.30} was used.

### Example 10

Raw materials were weighed to include 8.44 g of MgCO₃, 13.12 g of Ga₀O₃, 2.81 g of Al₂O₃, 0.38 g of Cr₂O₃. An oxide phosphor of Example 10 was obtained in the same manner as in Example 1 with the exception that a raw material mixture weighed such that the molar ratio of each element in the prepared composition was MgGa_{1.40}Al_{0.55}O₄:Cr_{0.05} was used. In Example 10, when the prepared composition was a composition included in the compositional formula represented by Formula (1), the second element M² was Al, and the variable v was 0.275.

### Example 11

Raw materials were weighed to include 8.44 g of MgCO₃, 9.37 g of Ga₂O₃, 4.85 g of Al₂O₃, and 0.38 g of Cr₂O₃. An oxide phosphor of Example 11 was obtained in the same manner as in Example 1 with the exception that a raw material mixture weighed such that the molar ratio of each element in the prepared composition was MgGaAl_{0.95}O₄:Cr_{0.05} was used. In Example 11, when the prepared composition was a composition included in the compositional formula represented by Formula (1), the second element M² was Al, and the variable v was 0.475.

### Example 12

Raw materials were weighed to include 5.90 g of MgCO₃, 2.44 g of ZnO, 17.91 g of Ga₂O₃, and 0.68 g of Cr₂O₃. An oxide phosphor of Example 12 was obtained in the same manner as in Example 1 with the exception that a raw material mixture weighed such that the molar ratio of each element in the prepared composition was Mg_{0.7}Zn_{0.3}Ga_{1.91}O₄:Cr_{0.09} was used. In Example 12, when the prepared composition was a composition included in the compositional formula represented by Formula (1), the first element M¹ was Zn, the variable t was 0.3, and the variable u was 1.

### Example 13

Raw materials were weighed to include 4.22 g of MgCO₃, 4.07 g of ZnO, 17.91 g of Ga₂O₃, and 0.68 g of Cr₂O₃. An oxide phosphor of Example 13 was obtained in the same manner as in Example 1 with the exception that a raw material mixture weighed such that the molar ratio of each element in the prepared composition was Mg_{0.5}Zn_{0.5}Ga_{1.91}O₄:Cr_{0.09} was used. In Example 13, when the prepared composition was a composition included in the compositional formula represented by Formula (1), the first element M¹ was Zn, the variable t was 0.5, and the variable u was 1.

### Example 14

Raw materials were weighed to include 5.90 g of MgCO₃, 2.44 g of ZnO, 9.37 g of Ga₂O₃, 4.64 g of Al₂O₃, and 0.68 g of Cr₂O₃. An oxide phosphor of Example 14 was obtained in the same manner as in Example 1 with the exception that a raw material mixture weighed such that the molar ratio of each element in the prepared composition was Mg_{0.7}Zn_{0.3}GaAl_{0.91}O₄:Cr_{0.09} was used. In Example 14, when the prepared composition was a composition included in the compositional formula represented by Formula (1), the first element M¹ was Zn, the second element M² was Al, the variable t was 0.3, the variable u was 1, and the variable v was 0.455.

### Example 15

Raw materials were weighed to include 4.22 g of MgCO₃, 4.07 g of ZnO, 9.37 g of Ga₂O₃, 4.64 g of Al₂O₃, and 0.68 g of Cr₂O₃. An oxide phosphor of Example 15 was obtained in the same manner as in Example 1 with the exception that a raw material mixture weighed such that the molar ratio of each element in the prepared composition was Mg_{0.5}Zn_{0.5}GaAl_{0.91}O₄:Cr_{0.09} was used. In Example 15, when the prepared composition was a composition included in the compositional formula represented by Formula (1), the first element M¹ was Zn, the second element M² was Al, the variable t was 0.5, the variable u was 1, and the variable v was 0.455.

### Comparative Example 1

Raw materials were weighed to include 8.44 g of MgCO₃, 18.70 g of Ga₂O₃, and 0.04 g of Cr₂O₃.

An oxide phosphor of Comparative Example 1 was obtained in the same manner as in Example 1 with the exception that a raw material mixture weighed such that the molar ratio of each element in the prepared composition was MgGa_{1.995}O₄:Cr_{0.005} was used. In the light emission spectrum of the oxide phosphor of Comparative Example 1 measured by the measurement method described below, the light emission peak wavelength was 709 nm, which is less than 800 nm.

### Comparative Example 2

Raw materials were weighed to include 8.44 g of MgCO₃, 18.65 g of Ga₂O₃, and 0.08 g of Cr₂O₃. An oxide phosphor of Comparative Example 2 was obtained in the same manner as in Example 1 with the exception that a raw material mixture weighed such that the molar ratio of each element in the prepared composition was MgGa_{1.99}O₄:Cr_{0.01} was used. In the light emission spectrum of the oxide phosphor of Comparative Example 2 measured by the measurement method described below, the light emission peak wavelength was 709 nm, which is less than 800 nm.

### Comparative Example 3

Raw materials were weighed to include 8.14 g of ZnO, 18.56 g of Ga₂O₃, and 0.08 g of Cr₂O₃. An oxide phosphor of Comparative Example 3 was obtained in the same manner as in Example 1 with the exception that a raw material mixture weighed such that the molar ratio of each element in the prepared composition was ZnGa_{1.99}O₄:Cr_{0.01} was used. In the light emission spectrum of the oxide phosphor of Comparative Example 3 measured by the measurement method described below, the light emission peak wavelength was 708 nm, which is less than 800 nm.

### Comparative Example 4

Raw materials were weighed to include 8.14 g of ZnO, 18.37 g of Ga₂O₃, and 0.24 g of Cr₂O₃. An oxide phosphor of Comparative Example 4 was obtained in the same manner as in Example 1 with the exception that a raw material mixture weighed such that the molar ratio of each element in the prepared composition was ZnGa_{1.97}O₄:Cr_{0.03} was used. In the light emission spectrum of the oxide phosphor of Comparative Example 4 measured by the measurement method described below, the light emission peak wavelength was 708 nm, which is less than 800 nm.

### Measurement of Median Particle Size (Median Size), Light Emission Spectrum, Absorption Spectrum, and Light Emission Characteristics

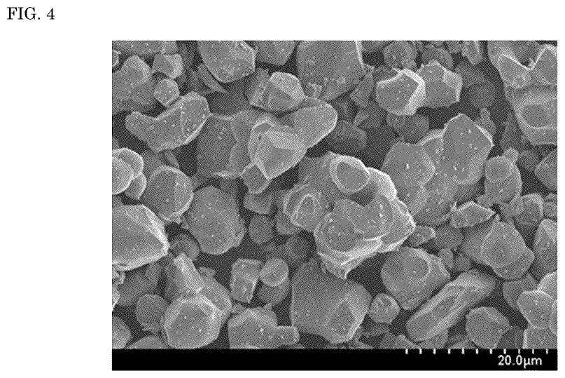

A laser diffraction-type particle size measuring device (MASTER SIZER 3000, available from Malvern Instruments Ltd.) was used to measure the 50% cumulative median particle size (median size) Dm from the small size side in the volume-based particle size distribution of the oxide phosphor of Example 3. The median particle size Dm of the oxide phosphor of Example 3 was 12.8 μm. FIG. 4 is an SEM photograph of the oxide phosphor of Example 3 captured by a scanning electron microscope (SEM).

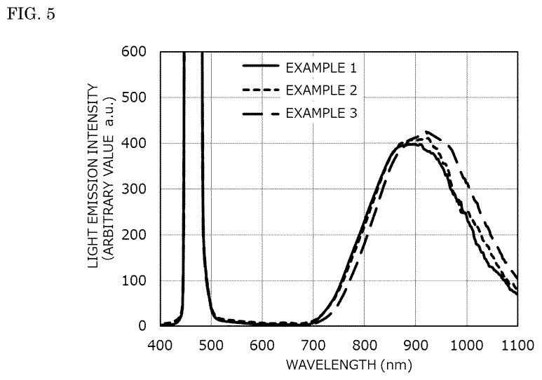

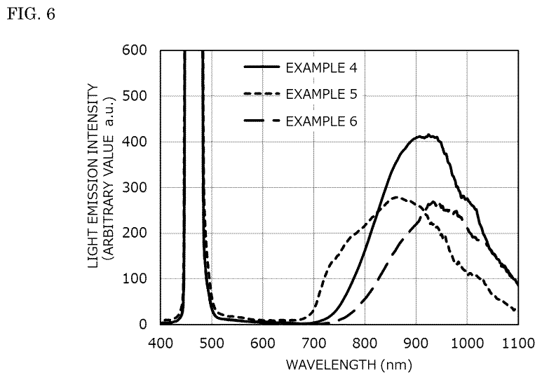

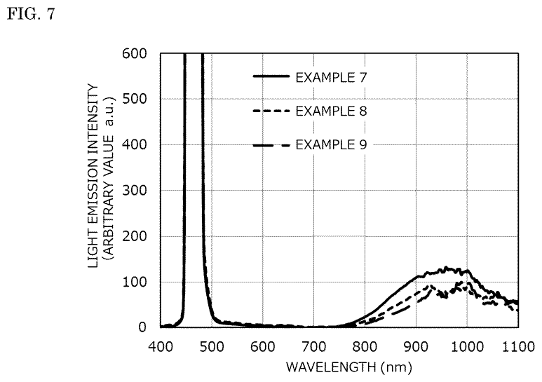

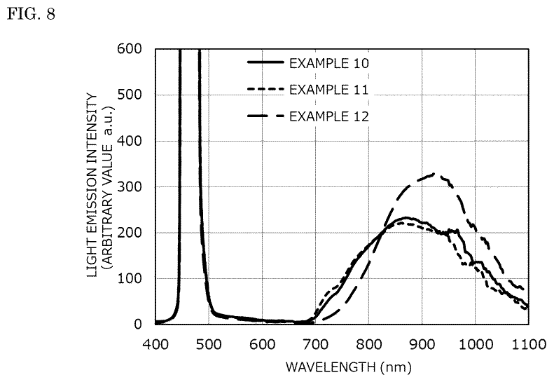

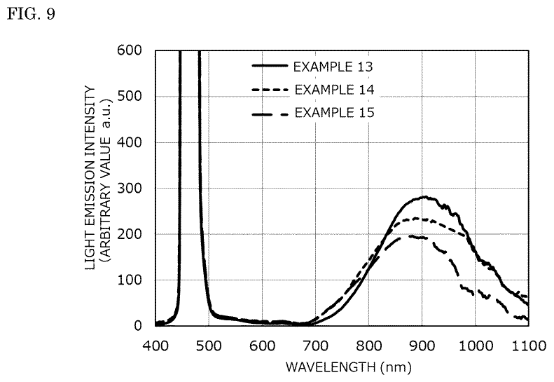

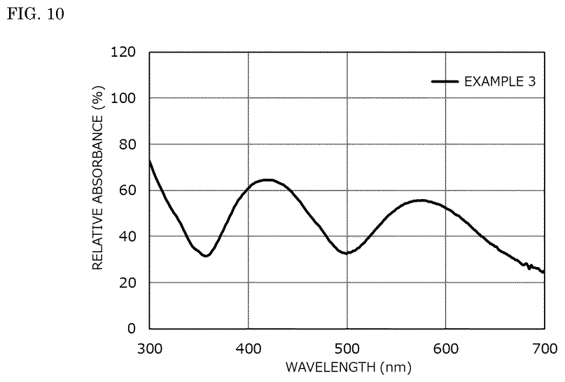

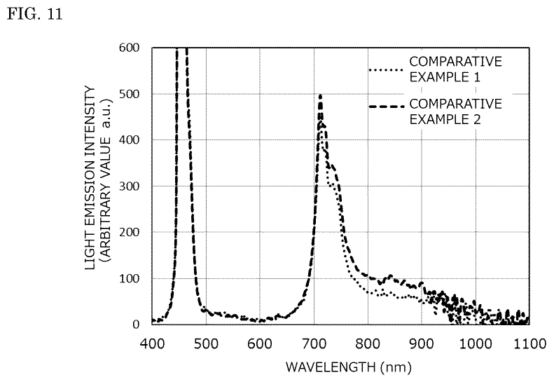

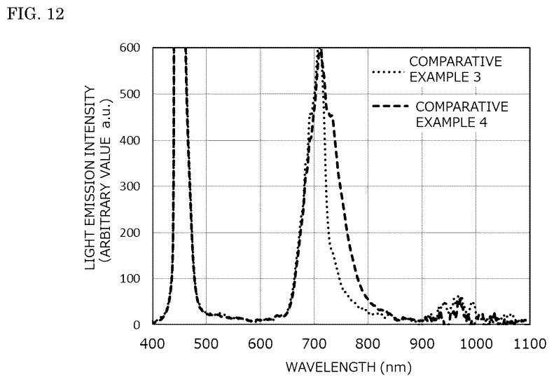

The light emission spectra of each of the oxide phosphors of the Examples and Comparative Examples were measured using a quantum efficiency measurement system (QE-2000, available from Otsuka Electronics Co., Ltd.). The light emission peak wavelength of the excitation light used in the quantum efficiency measurement system was 450 nm. Moreover, the absorption spectrum of the oxide phosphor of Example 3 in the wavelength range of from 200 nm to 700 nm was measured using the quantum efficiency measurement system (QE-2000, available from Otsuka Electronics Co., Ltd.). From the obtained light emission spectra of each phosphor, the relative light emission intensity (%), the light emission peak wavelength (λp) (nm), and the full width at half maximum (FWHM) (nm) were obtained as light emission characteristics. For the relative light emission intensity, the light emission intensity at the light emission peak wavelength of the oxide phosphor according to Example 9 had the lowest light emission intensity, and thus the relative light emission intensity at the light emission peak wavelength of each oxide phosphor was determined on the basis of the light emission intensity at the light emission peak wavelength of the oxide phosphor according to Example 9 being 100%. The results are indicated in Table 1. Also, FIG. 5 illustrates the light emission spectra of the oxide phosphors according to Examples 1 to 3. FIG. 6 illustrates the light emission spectra of the oxide phosphors according to Examples 4 to 6. FIG. 7 illustrates the light emission spectra of the oxide phosphors according to Examples 7 to 9. FIG. 8 illustrates the light emission spectra of the oxide phosphors according to Examples 10 to 12. FIG. 9 illustrates the light emission spectra of the oxide phosphors according to Examples 13 to 15. FIG. 10 illustrates an absorption spectrum in a range from 300 nm to 700 nm of the oxide phosphor according to Example 3. In FIG. 10, the relative absorbance (%) in a range from 300 nm to 700 nm is illustrated on the basis of the maximum absorbance of the absorption spectrum near 250 nm being 100%. FIG. 11 illustrates the light emission spectra of the oxide phosphors according to Comparative Examples 1 and 2. FIG. 12 illustrates the light emission spectra of the oxide phosphors according to Comparative Examples 3 and 4. In FIGS. 5 to 9, 11, and 12, the light emission spectra in the range from 400 nm to 500 nm are the light emission spectra of the excitation light.

TABLE 1

| | | Oxide Phosphor | | |
|---|---|---|---|---|
| | | Light Emission | | Relative Light |
| | | Peak Wavelength | Full Width At Half | Emission Intensity |
| | Prepared Compsition | λ p (nm) | Maximum (FWHM) (nm) | (%) |
| Example 1 | MgGa_{1.95}O₄:Cr_{0.05} | 890 | 210 | 349.4 |
| Example 2 | MgGa_{1.93}O₄:Cr_{0.07} | 890 | 220 | 370.7 |
| Example 3 | MgGa_{1.91}O₄:Cr_{0.09} | 890 | 210 | 406.9 |
| Example 4 | MgGa_{1.90}O₄:Cr_{0.10} | 890 | 200 | 350.8 |
| Example 5 | MgGa_{1.97}O₄:Cr_{0.03} | 845 | 220 | 242.8 |
| Example 6 | MgGa_{1.85}O₄:Cr_{0.15} | 940 | 220 | 253.4 |
| Example 7 | MgGa_{1.80}O₄:Cr_{0.20} | 950 | 220 | 131.7 |
| Example 8 | MgGa_{1.75}O₄:Cr_{0.25} | 980 | 200 | 104.0 |
| Example 9 | MgGa_{1.70}O₄:Cr_{0.30} | 980 | 200 | 100.0 |
| Example 10 | MgGa_{1.40}Al_{0.55}O₄:Cr_{0.05} | 850 | 240 | 266.3 |
| Example 11 | MgGaAl_{0.95}O₄:Cr_{0.05} | 840 | 210 | 230.1 |
| Example 12 | Mg_{0.7}Zn_{0.3}Ga_{1.91}O₄:Cr_{0.09} | 910 | 200 | 290.4 |
| Example 13 | Mg_{0.5}Zn_{0.5}Ga_{1.91}O₄:Cr_{0.09} | 900 | 200 | 243.3 |
| Example 14 | Mg_{0.7}Zn_{0.3}GaAl_{0.91}O₄:Cr_{0.09} | 890 | 220 | 262.4 |
| Example 15 | Mg_{0.5}Zn_{0.5}GaAl_{0.91}O₄:Cr_{0.09} | 870 | 200 | 160.2 |
| Comparative | MgGa_{1.995}O₄:Cr_{0.005} | 709 | 50 | 141.3 |
| Example 1 | | | | |
| Comparative | MgGa_{1.99}O₄:Cr_{0.01} | 709 | 50 | 177.0 |
| Example 2 | | | | |
| Comparative | ZnGa_{1.99}O₄:Cr_{0.01} | 708 | 35 | 160.9 |
| Example 3 | | | | |
| Comparative | ZnGa_{1.97}O₄:Cr_{0.03} | 708 | 60 | 187.7 |
| Example 4 | | | | |

As shown in Table 1 or FIGS. 5 to 9, the light emission spectra of the oxide phosphors according to Examples 1 to 15 had light emission peak wavelengths in a range from 800 nm to 1000 nm and full width at half maximum (FWHM) values of 150 nm or more. The oxide phosphors according to Examples 1 to 15 had light emission peak wavelengths in the near-infrared light wavelength range from 800 nm to 1000 nm, and had light emission spectra with wide full width at half maximums of 150 nm or more, and more specifically of 200 nm or more. FIG. 10 illustrates the absorption spectrum of the oxide phosphor according to Example 3. From FIG. 10, it is clear that peaks with relatively high absorption rates are present in a range from 400 nm to 450 nm and in a range from 550 nm to 600 nm.

As shown in Table 1 or FIG. 11, the oxide phosphors according to Comparative Examples 1 and 2 had a molar ratio of Cr of less than 0.2 per mole of the composition of the oxide phosphor, and while the relative light emission intensities were higher than that of the oxide phosphor according to Example 9 for example, the light emission peak wavelengths were 709 nm, which is less than 800 nm. In addition, as shown in Table 1 or FIG. 12, when irradiated with excitation light having an emission peak wavelength of 450 nm, the oxide phosphors according to Comparative Examples 3 and 4 had light emission peak wavelengths of 708 nm, which is less than 800 nm. The molar ratio of Cr of the oxide phosphor according to Comparative Example 4 was 0.02 or more per mole of the composition of the oxide phosphor, but Mg was not contained in the composition of the oxide phosphor, and the molar ratio of Zn serving as the first element M¹ contained as necessary per mole of the composition of the oxide phosphor exceeded 0.8, and therefore, the light emission peak wavelength was less than 800 nm.

### Light-Emitting Device According to Examples

A phosphor represented by the following prepared composition and having the following light emission peak wavelength when excited by a light-emitting element having a light emission peak wavelength of 450 nm was used for a wavelength conversion member used in a light-emitting device.

### First Phosphor

Formula (1-1): MgGa_{1.95}O₄:Cr_{0.05}, light emission peak wavelength of 890 nm.

### Third Phosphor

Formula (3b-1): Lu₃Al₅O₁₂:Ce, light emission peak wavelength of 520 nm.

### Fourth Phosphor

Formula (4a-1): (Sr, Ca)AlSiN₃:Eu, light emission peak wavelength of 620 nm.

Formula (4a-2): CaAlSiN₃:Eu, light emission peak wavelength of 660 nm.

### Fifth Phosphor

Formula (5a): Ga₂O₃:Cr, light emission peak wavelength of 730 nm.

### Light-Emitting Device of Example 1

The oxide phosphor according to Example 1 was used as the first phosphor. The third phosphor, the fourth phosphor, and the fifth phosphor shown in Table 2 were mixed and dispersed with a silicone resin at the blending amounts shown in Table 2, after which the mixture was further defoamed, and a wavelength conversion member-forming composition was obtained. Table 2 shows the blending amounts in terms of parts by mass of the first phosphor, the third phosphor, the fourth phosphor, and the fifth phosphor per 100 parts by mass of the resin for each of the Examples and Comparative Examples. The total amount of the phosphors in the wavelength conversion member-forming composition was 179.7 parts by mass per 100 parts by mass of the resin. Subsequently, a molded body having a recess as illustrated in FIG. 2 was prepared, and a light-emitting element having a light emission peak wavelength at 443 nm and having a gallium nitride-based compound semiconductor was disposed on a first lead on the bottom surface of the recess. The light emission peak wavelength of the light-emitting element was 443 nm, and the full width at half maximum of the light emission spectrum was 15 nm. After the light-emitting element was disposed on the first lead, the wavelength conversion member-forming composition was injected onto the light-emitting element to fill the recess, and further heated to cure the resin in the wavelength member-forming composition. Note that the light-emitting device of Example 1 did not include the second phosphor 72 in the wavelength conversion member illustrated in FIG. 2. A light-emitting device according to the example was produced through such steps.

### Light-Emitting Device of Example 2

A light-emitting device according to Example 2 and a light-emitting device according to Example 3 were produced in the same manner as the light-emitting device according to Example 1 with the exception that a wavelength conversion member-forming composition was prepared such that the blending amounts of each of the first phosphor, the third phosphor, the fourth phosphor, and the fifth phosphor per 100 parts by mass of the resin were as shown in Table 2, and the wavelength conversion member-forming composition was used.

### Measurement of Light Emission Spectrum

The light emission spectra at room temperature (25° C.±5° C.) of the light-emitting devices of the examples were measured using an optical measurement system that combined a spectrophotometer (PMA-11, available from Hamamatsu Photonics K.K.) and an integrating sphere. For each light-emitting device, in the light emission spectrum of each light-emitting device, the maximum value of the light emission intensity in a range from the light emission peak wavelength of the light-emitting element to 900 nm was is defined as 100%, and the minimum relative light emission intensity in the range from the light emission peak wavelength of the light-emitting element to 900 nm was determined (minimum relative light emission intensity (%)=(minimum light emission intensity)/(maximum light emission intensity)×100). The results are indicated in Table 2.

TABLE 2

| | | Phosphor | | | | | Light-Emitting Device |
|---|---|---|---|---|---|---|---|
| | | First Phosphor | | Fourth phosphor | | Fifth phosphor | Minimum Relative |
| | | (Parts by mass) | Third phosphor | (Parts by mass) | | (Parts by mass) | Light Emission |
| | Resin | (1-1) | (3b-1) | (4a-1) | (4a-2) | (5a) | Intensity |
| | (Parts by mass) | MgGa_{1.95}O₄:Cr_{0.05} | Lu₃Al₅O₁₂:Ce | (Sr, Ca)AlSiN₃:Eu | CaAlSiN₃:Eu | Ga₂O₃:Cr | (%) |
| Example 1 | 100.0 | 109.8 | 180.0 | 17.0 | 15.7 | 27.4 | 4.1 |
| Example 2 | 100.0 | 88.0 | 120.0 | 11.3 | 10.5 | 20.4 | 5.7 |

The light-emitting devices according to Examples 1 and 2 emitted light in which the minimum value of the light emission intensity in the range from 443 nm to 1000 nm in the light emission spectrum was 3% or more when the maximum value of the light emission intensity in a range from 443 nm to 900 nm was is defined as 100%.

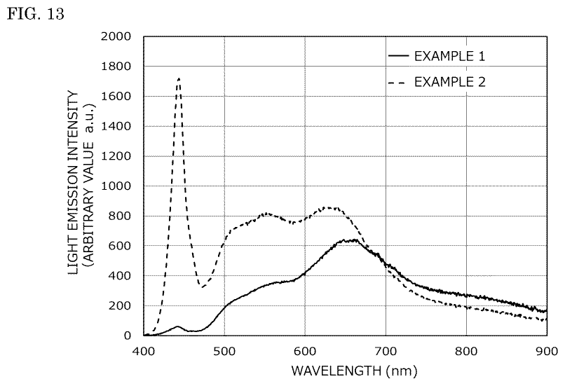

FIG. 13 is a graph illustrating light emission spectra of the light-emitting devices according to Examples 1 and 2. The light emission spectra of the light-emitting devices according to Examples 1 and 2 were continuous within a range from the light emission peak wavelength of the light-emitting element to 900 nm, and on the basis of the maximum light emission intensity in the range from the light emission peak wavelength of the light-emitting element to 900 nm being 100%, the light-emitting devices emitted light with the minimum light emission intensity in the range from the light emission peak wavelength of the light-emitting element to 900 nm being 3% or higher, and the light-emitting devices could irradiate, from the light source, light having a light emission spectrum in a range from visible light to a wavelength including a portion of infrared light.

### Example 16

Raw materials were weighed to include 7.94 g of MgCO₃, 0.45 g of NiO, 18.29 g of Ga₂O₃, and 0.38 g of Cr₂O₃. Each element per mole of the composition of the obtained oxide phosphor was weighed such that the molar ratio of each element in the prepared composition was Mg_{0.94}Ni_{0.06}Ga_{1.95}O₄:Cr_{0.05}. The raw materials were mixed for 10 minutes using an agate mortar and an agate pestle to obtain a raw material mixture. The obtained raw material mixture was placed in an alumina crucible and heat-treated at 1400° C. in an air atmosphere (20 vol % of oxygen) at standard atmospheric pressure (0.101 MPa) for 6 hours. After the heat treatment, the obtained heat-treated product was pulverized, and an oxide phosphor of Example 16 was obtained.

### Example 17

Raw materials were weighed to include 8.19 g of MgCO₃, 0.23 g of NiO, 18.29 g of Ga₂O₃, and 0.38 g of Cr₂O₃. An oxide phosphor of Example 17 was obtained in the same manner as in Example 16 with the exception that each element per mole of the composition of the obtained oxide phosphor was weighed such that the molar ratio of each element in the prepared composition was Mg_{0.97}Ni_{0.03}Ga_{1.95}O₄:Cr_{0.05}.

### Example 18

Raw materials were weighed to include 8.19 g of MgCO₃, 0.23 g of NiO, 17.91 g of Ga₂O₃, and 0.69 g of Cr₂O₃. An oxide phosphor of Example 18 was obtained in the same manner as in Example 16 with the exception that each element per mole of the composition of the obtained oxide phosphor was weighed such that the molar ratio of each element in the prepared composition was Mg_{0.97}Ni_{0.03}Ga_{1.91}O₄:Cr_{0.09}.

### Example 19

Raw materials were weighed to include 7.94 g of MgCO₃, 0.45 g of NiO, 17.91 g of Ga₂O₃, and 0.69 g of Cr₂O₃. An oxide phosphor of Example 19 was obtained in the same manner as in Example 16 with the exception that each element per mole of the composition of the obtained oxide phosphor was weighed such that the molar ratio of each element in the prepared composition was Mg_{0.94}Ni_{0.06}Ga_{1.91}O₄:Cr_{0.09}.

### Example 20

Raw materials were weighed to include 7.60 g of MgCO₃, 0.75 g of NiO, 17.91 g of Ga₂O₃, and 0.69 g of Cr₂O₃. An oxide phosphor of Example 20 was obtained in the same manner as in Example 16 with the exception that each element per mole of the composition of the obtained oxide phosphor was weighed such that the molar ratio of each element in the prepared composition was Mg_{0.90}Ni_{0.10}Ga_{1.91}O₄:Cr_{0.09}.

### Example 21

Raw materials were weighed to include 8.19 g of MgCO₃, 0.23 g of NiO, 18.47 g of Ga₂O₃, and 0.23 g of Cr₂O₃. An oxide phosphor of Example 21 was obtained in the same manner as in Example 16 with the exception that each element per mole of the composition of the obtained oxide phosphor was weighed such that the molar ratio of each element in the prepared composition was Mg_{0.97}Ni_{0.03}Ga_{1.97}O₄:Cr_{0.03}.

### Example 22

Raw materials were weighed to include 8.32 g of MgCO₃, 0.12 g of NiO, 17.91 g of Ga₂O₃, and 0.69 g of Cr₂O₃. An oxide phosphor of Example 22 was obtained in the same manner as in Example 16 with the exception that each element per mole of the composition of the obtained oxide phosphor was weighed such that the molar ratio of each element in the prepared composition was Mg_{0.985}Ni_{0.015}Ga_{1.91}O₄:Cr_{0.09}.

### Example 23

Raw materials were weighed to include 8.25 g of MgCO₃, 0.18 g of NiO, 17.91 g of Ga₂O₃, and 0.69 g of Cr₂O₃. An oxide phosphor of Example 23 was obtained in the same manner as in Example 16 with the exception that each element per mole of the composition of the obtained oxide phosphor was weighed such that the molar ratio of each element in the prepared composition was Mg_{0.977}Ni_{0.023}Ga_{1.91}O₄:Cr_{0.09}.

### Example 24

Raw materials were weighed to include 8.39 g of MgCO₃, 0.05 g of NiO, 17.91 g of Ga₂O₃, and 0.69 g of Cr₂O₃. An oxide phosphor of Example 24 was obtained in the same manner as in Example 16 with the exception that each element per mole of the composition of the obtained oxide phosphor was weighed such that the molar ratio of each element in the prepared composition was Mg_{0.993} Ni_{0.007}Ga_{1.91}O₄:Cr_{0.09}.

### Measurement of Light Emission Characteristics

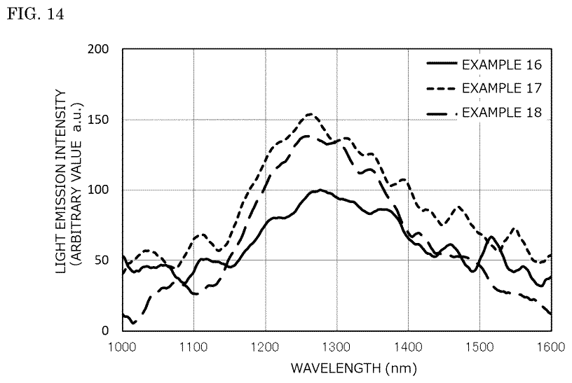

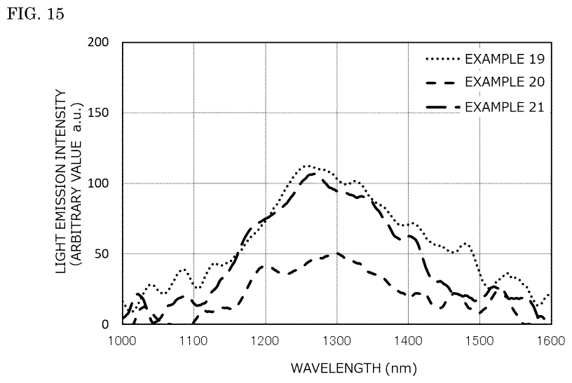

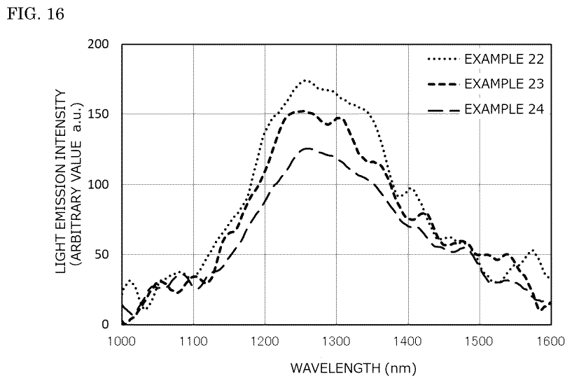

The light emission spectrum of each of the obtained oxides of the Examples was measured using a quantum efficiency measurement system (QE-2000, available from Otsuka Electronics Co., Ltd.) by the same method as the method for measuring the light emission characteristics described above. The light emission peak wavelength of the excitation light used in the quantum efficiency measurement system was 450 nm. From the obtained light emission spectra of each phosphor, the relative light emission intensity (%), the light emission peak wavelength (λp) (nm), and the full width at half maximum (FWHM) (nm) were obtained as light emission characteristics. For the relative light emission intensity, the light emission intensity at the light emission peak wavelength of the oxide phosphor according to Example 16 had the lowest light emission intensity among the oxide phosphors of Examples 16 to 24, and thus the relative light emission intensity at the light emission peak wavelength of each oxide phosphor was determined on the basis of the light emission intensity at the light emission peak wavelength of the oxide phosphor according to Example 16 being 100%. The results are shown in Table 3. Moreover, FIG. 5 illustrates the light emission spectra of the oxide phosphors according to Examples 1 to 3 in a range from 1000 nm to 1600 nm. FIG. 14 illustrates the light emission spectra of the oxide phosphors according to Examples 16 to 18 in a range from 100 nm to 1600 nm. FIG. 15 illustrates the emission spectra of oxide phosphors according to Examples 19 to 21. Moreover, FIG. 16 illustrates the emission spectra of the oxide phosphors according to Examples 22 to 24 in a range from 1000 nm to 1600 nm.

TABLE 3

| | | Oxide Phosphor | | |
|---|---|---|---|---|
| | | Light Emission | | Relative Light |
| | | Peak Wavelength | Full Width At Half | Emission Intensity |
| | Prepared Compsition | λ p (nm) | Maximum (FWHM) (nm) | (%) |
| Example 16 | Mg_{0.94}Ni_{0.06}Ga_{1.95}O₄:Cr_{0.05} | 1277 | 313 | 100.0 |
| Example 17 | Mg_{0.97}Ni_{0.03}Ga_{1.95}O₄:Cr_{0.05} | 1263 | 328 | 153.7 |
| Example 18 | Mg_{0.97}Ni_{0.03}Ga_{1.91}O₄:Cr_{0.09} | 1264 | 246 | 138.6 |
| Example 19 | Mg_{0.94}Ni_{0.06}Ga_{1.91}O₄:Cr_{0.09} | 1261 | 268 | 112.5 |
| Example 20 | Mg_{0.90}Ni_{0.10}Ga_{1.91}O₄:Cr_{0.09} | 1298 | 208 | 50.7 |
| Example 21 | Mg_{0.97}Ni_{0.03}Ga_{1.97}O₄:Cr_{0.03} | 1268 | 251 | 106.8 |
| Example 22 | Mg_{0.985}Ni_{0.015}Ga_{1.91}O₄:Cr_{0.09} | 1257 | 247 | 174.3 |
| Example 23 | Mg_{0.977}Ni_{0.023}Ga_{1.91}O₄:Cr_{0.09} | 1256 | 263 | 152.5 |
| Example 24 | Mg_{0.993}Ni_{0.007}Ga_{1.91}O₄:Cr_{0.09} | 1254 | 257 | 125.4 |

As shown in Table 3 or FIGS. 14 to 16, the oxide phosphors of examples 16 to 24 had, in the light emission spectra, light emission peak wavelengths in a range from 800 nm to 1600 nm, and more specifically in a range from 1001 nm to 1600 nm, and had full width at half maximum (FWHM) values of 150 nm or more. The oxide phosphors according to Examples 1 to 15 had light emission peak wavelengths in the near-infrared light wavelength range from 800 nm to 1600 nm, and had light emission spectra with wide full width at half maximum values of 150 nm or more, and more specifically of 330 nm or more.

### INDUSTRIAL APPLICABILITY

The oxide phosphor according to the present disclosure can also be used in a medical light-emitting device for obtaining in vivo information, a light-emitting device mounted on a small mobile device such as a smartphone for physical condition management, a light-emitting device for an analyzer for nondestructively measuring internal information of food products such as fruits, vegetables, and rice, and a light-emitting device of a reflection spectroscopic measurement device used to measure film thickness or the like.

### REFERENCE SIGNS LIST

10: Light-emitting element
11: Semiconductor element
20: First lead
30: Second lead
40: Molded body
42: Resin portion
50, 51: Wavelength conversion member
52: Wavelength conversion body
53: Light-transmitting body
60: Wire
61: Conductive member
70 Phosphor
71: First phosphor
72 Second phosphor
73: Third phosphor
74 Fourth phosphor
75 Fifth phosphor
80 Adhesive layer
90: Cover member
100, 200: Light-emitting device

What is claimed is:

1.-16. (canceled)

17. An oxide phosphor having a composition comprising Mg, Ga, O, and Cr, the composition optionally including: at least one first element M¹ selected from the group consisting of Ca, Sr, Ba, Ni, and Zn; at least one second element M² selected from the group consisting of B, Al, In, and Sc; and at least one third element M³ selected from the group consisting of Eu, Ce, Tb, Pr, Nd, Sm, Yb, Ho, Er, Tm, and Mn,
wherein, when a total molar ratio of Ga, Cr, the second element M², and the third element M³ per mole of the composition of the oxide phosphor is 2, a molar ratio of Mg or a molar ratio of a total of Mg and the first element M¹ when the first element M¹ is included is in a range of 0.7 to 1.3,
a molar ratio of O is in a range of 3.7 to 4.3,
a molar ratio of Cr is in a range greater than 0.02 and 0.3 or less, and
further, when a molar ratio of a total of Mg and the first element M¹ is 1, a molar ratio of the first element M¹ is in a range of 0 to 0.8, and
a molar ratio of the second element M² is in a range of 0 to 1.6, a molar ratio of the third element M³ is in a range of 0 to 0.2, the molar ratio of the third element M³ being smaller than the molar ratio of Cr, and
wherein the oxide phosphor has a light emission peak wavelength in a range of 800 nm to 1600 nm.

18. The oxide phosphor according to claim 17, having a composition represented by Formula (1) below: 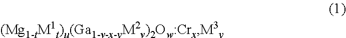
where in Formula (1), t, u, v, w, x, and y satisfy: 0≤t≤0.8; 0.7≤u≤1.3; 0≤v≤0.8; 3.7≤w≤4.3; 0.02<x≤0.3; 0≤y≤0.2; and y<x.

19. The oxide phosphor according to claim 17, wherein the first element M¹ is at least one element selected from the group consisting of Ca, Sr, Ni and Zn, the second element M² is at least one element selected from the group consisting of Al and Sc, and the third element M³ is at least one element selected from the group consisting of Eu, Ce and Mn.

20. The oxide phosphor according to claim 17, wherein the first element M¹ is Ni, and a molar ratio of the first element M¹ is in a range of 0.001 to 0.50 when a molar ratio of a total of Mg and the first element M¹ is 1.

21. The oxide phosphor according to claim 18, wherein the first element M¹ is Ni, and in Formula (1), t satisfies 0.001≤t≤0.50.

22. The oxide phosphor according to claim 17, wherein a full width at half maximum of the oxide phosphor in a light emission spectrum having the light emission peak wavelength is 150 nm or greater.

23. A light-emitting device comprising:
the oxide phosphor according to claim 17; and
a light-emitting element having a light emission peak wavelength in a range of 365 nm to 500 nm, the light-emitting element irradiating the oxide phosphor.

24. The light-emitting device according to claim 7, comprising:
as an essential component, the oxide phosphor according to claim 17 as a first phosphor; and
at least one phosphor selected from the group consisting of: a second phosphor having a light emission peak wavelength in a range of 455 nm to less than 495 nm in a light emission spectrum of the second phosphor: a third phosphor having a light emission peak wavelength in a range of 495 nm to less than 610 nm in a light emission spectrum of the third phosphor; a fourth phosphor having a light emission peak wavelength in a range of 610 nm to less than 700 nm in a light emission spectrum of the fourth phosphor; and a fifth phosphor having a light emission peak wavelength in a range of 700 nm to 1050 nm in a light emission spectrum of the fifth phosphor,
wherein the light-emitting device has a light emission spectrum such that, when a maximum value of light emission intensity in a range of the light emission peak wavelength of the light-emitting element to 900 nm is defined as 100%, a minimum value of light emission intensity in the range of the light emission peak wavelength of the light-emitting element to 900 nm is 3% or higher.

25. The light-emitting device according to claim 24, wherein the second phosphor comprises at least one phosphor selected from the group consisting of a phosphate phosphor having a composition represented by Formula (2a) below, an aluminate phosphor having a composition represented by Formula (2b) below, and an aluminate phosphor having a composition represented by Formula (2c) below:

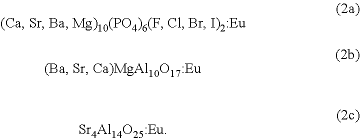

26. The light-emitting device according to claim 24, wherein the third phosphor comprises at least one phosphor selected from the group consisting of a silicate phosphor having a composition represented by Formula (3a) below, an aluminate phosphor or a gallate phosphor having a composition represented by Formula (3b) below, a β-sialon phosphor having a composition represented by Formula (3c) below, a cesium-lead halide phosphor having a composition represented by Formula (3d) below, and a nitride phosphor having a composition represented by formula (3e) below:

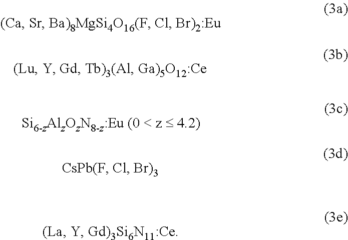

27. The light-emitting device according to claim 24, wherein the fourth phosphor comprises at least one phosphor selected from the group consisting of a nitride phosphor having a composition represented by Formula (4a) below, a fluorogermanate phosphor having a composition represented by Formula (4b) below, an oxynitride phosphor having a composition represented by Formula (4c) below, a fluoride phosphor having a composition represented by Formula (4d) below, a fluoride phosphor having a composition represented by formula (4e) below, a nitride phosphor having a composition represented by formula (4f) below, and a nitride phosphor having a composition represented by formula (4g) below: 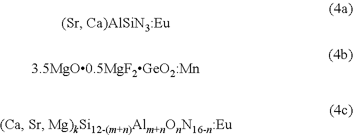
where in Formula (4c), k, m, and n satisfy 0<k≤2.0, 2.0≤m≤6.0, and 0≤n≤2.0, 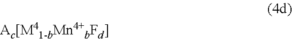
where in Formula (4d), A includes at least one ion selected from the group consisting of K⁺, Li⁺, Na⁺, Rb⁺, Cs⁺, and NH₄⁺, M⁴ includes at least one element selected from the group consisting of Group 4 elements and Group 14 elements, b satisfies 0<b<0.2, c is an absolute value of a charge of the [M⁴_{1-b}Mn⁴⁺_{b}F_{d}] ion, and d satisfies 5<d<7, 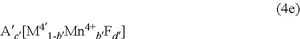
where in Formula (4e), A′ includes at least one ion selected from the group consisting of K⁺, Li⁺, Na⁺, Rb⁺, Cs⁺, and NH₄⁺, M^{4′} includes at least one element selected from the group consisting of Group 4 elements, Group 13 elements, and Group 14 elements, b′ satisfies 0<b′<0.2, c′ is an absolute value of a charge of the [M^{2′}_{1-b′}Mn⁴⁺_{b′}F_{d′}] ion, and d′ satisfies 5<d′<7,

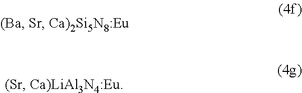

28. The light-emitting device according to claim 24, wherein the fifth phosphor comprises at least one phosphor selected from the group consisting of a gallate phosphor having a composition represented by Formula (5a) below, an aluminate phosphor having a composition represented by Formula (5b) below, a gallate phosphor having a composition represented by Formula (5c) below, an aluminate phosphor having a composition represented by Formula (5d) below, and a phosphor having a composition represented by Formula (5e) below: 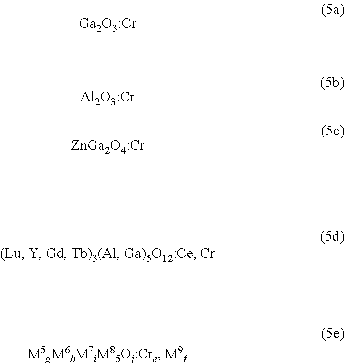
where in Formula (Se), M⁵ is at least one element selected from the group consisting of Li, Na, Ka, Rb and Cs, M⁶ is at least one element selected from the group consisting of Mg, Ca, Sr, Ba and Zn, M⁷ is at least one element selected from the group consisting of Ba, Al, Ga, In and rare earth elements, M⁸ is at least one element selected from the group consisting of Si, Ti, Ge, Zr, Sn, Hf and Pb, and M⁹ is at least one element selected from the group consisting of Eu, Ce, Tb, Pr, Nd, Sm, Yb, Ho, Er, Tm, Ni and Mn, and e, f, g, h, i, and j satisfy: 0<e≤0.2; 0≤f≤0.1; f<e, 0.7≤g≤1.3; 1.5≤h≤2.5:0.7≤i≤1.3; and 12.9≤j≤15.1.

29. A method for producing an oxide phosphor, the method comprising:
preparing a raw material mixture comprising a first compound containing Mg, a second compound containing Ga, and a third compound containing Cr, and optionally a fourth compound containing at least one first element M¹ selected from the group consisting of Ca, Sr, Ba, Ni, and Zn, and optionally a fifth compound containing at least one second element M² selected from the group consisting of B, Al, In, and Sc, and optionally a sixth compound containing at least one third element M³ selected from the group consisting of Eu, Ce, Tb, Pr, Nd, Sm, Yb, Ho, Er, Tm, and Mn,
wherein the raw material mixture has a composition in which when a total molar ratio of Ga, Cr, the second element M², and the third element M³ per mole of the composition is 2, a molar ratio of Mg, or when the first element M¹ is included, a molar ratio of a total of Mg and the first element M¹ is in a range of 0.7 to 1.3, a molar ratio of Cr is in a range greater than 0.02 and 0.3 or less, when a molar ratio of a total of Mg and the first element M¹ is 1, a molar ratio of the first element M¹ is in a range of 0 to 0.8, a molar ratio of the second element M² is in a range of 0 to 1.6, a molar ratio of the third element M³ is in a range of 0 to 0.2, and the molar ratio of the third element M³ is smaller than the molar ratio of Cr; and
obtaining an oxide phosphor by heat-treating the raw material mixture in an atmosphere containing oxygen at a temperature in a range of 1200° C. to 1700° C.,
wherein at least one selected from the group consisting of the first compound, the second compound, and the third compound is an oxide.

30. The method for producing an oxide phosphor according to claim 29, wherein the raw material mixture has a composition represented by Formula (1) below: 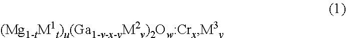
where in Formula (1), t, u, v, w, x, and y satisfy 0≤t≤0.8, 0.7≤u≤1.3, 0≤v≤0.8, 3.7≤w≤4.3, 0.02<x≤0.3, 0≤y≤0.2, and y<x.

31. The method for producing an oxide phosphor according to claim 29, wherein the atmosphere in which the heat-treatment is performed is an air atmosphere.

32. The method for producing an oxide phosphor according to claim 29, wherein the temperature at which the heat-treatment is performed is in a range of 1300° C. to 1600° C.
